(19) United States
(12) Patent Application Publication
(10) Pub. No.: US 2025/0192670 A1
(43) Pub. Date: Jun. 12, 2025

(54) INTEGRATED GAN POWER DEVICES INCLUDING PFC AND QR FLYBACK CONTROLLERS

(71) Applicant: Navitas Semiconductor Limited, Dublin (IE)

(72) Inventors: Chien-Chun HUANG, Taoyuan City (TW); Milind GUPTA, San Jose, CA (US); Kai-Fang WEI, San Jose, CA (US); Xiucheng HUANG, Torrance, CA (US); Weijing DU, Torrance, CA (US); Renxiong ZHAN, Shanghai (CN); Chih-Hsien HSIEH, Changhua County 515 (TW); Mingjie LI, Shenzhen (CN); Chi-Chih CHANG, Taoyuan City (TW); Tao LIU, San Marino, CA (US); Songming ZHOU, Shanghai (CN); Zhengdong ZHANG, Shanghai (CN)

(73) Assignee: Navitas Semiconductor Limited, Dublin (IE)

(21) Appl. No.: 18/975,373

(22) Filed: Dec. 10, 2024

Related U.S. Application Data
(60) Provisional application No. 63/608,792, filed on Dec. 11, 2023.

(30) Foreign Application Priority Data
Dec. 11, 2023 (CN) 202311698842.4
Nov. 11, 2024 (CN) 202411603967.9

(51) Int. Cl. H02M 1/42; H02M 1/08; H02M 3/00; H02M 3/155; H10D 62/85

(52) U.S. Cl. CPC H02M 1/4241; H02M 1/08; H02M 3/01; H02M 3/155; H10D 62/8503

(57) ABSTRACT

An electronic component. The electronic component includes a base; a first semiconductor device attached to the base and having: a first Gallium nitride (GaN)-based switch having a first gate, a first source and a first drain, the first gate arranged to control a current flow between the first source and the first drain; a second GaN-based switch having a second source, a second gate and a second drain, the second gate coupled to the first gate, and the second drain coupled to the first drain. In one aspect, the electronic component also includes a second semiconductor device attached to the base and having: a logic circuit coupled to the second source and arranged to detect a magnitude of the current flow; and a driver circuit coupled to the first and second gates, the driver circuit arranged to control on and off states of the first and second GaN-based switches.

### CROSS REFERENCE TO RELATED APPLICATIONS

This application claims priority to U.S. provisional patent application No. 63/608,792, for “POWER FACTOR CORRECTION CONTROLLER CIRCUIT AND AN INTEGRATED GAN POWER DEVICE” filed on Dec. 11, 2023, and to CN provisional patent application No. 20/231,1698842.4, for “PACKAGE FOR HIGH-VOLTAGE POWER DEVICE AND PACKAGE FOR HIGH-VOLTAGE POWER DEVICE AND CONTROLLER CO-PACKAGE” filed on Dec. 11, 2023, and to CN provisional patent application No. 20/241,1603967.9, for “QR FLYBACK CONTROLLER SWITCHER IN A DPAK-4L PACKAGE” filed on Nov. 11, 2024, the contents of all of which are hereby incorporated by reference in their entirety for all purposes.

### FIELD

The described embodiments relate generally to power converters, and more particularly, the present embodiments relate to integrated gallium nitride (GaN) power devices including power factor correction (PFC) controllers and/or quasi-resonant (QR) flyback controllers.

### BACKGROUND

Electronic devices such as computers, servers and televisions, among others, employ one or more electrical power conversion circuits to convert one form of electrical energy to another. Some electrical power conversion circuits convert a high (or low) DC voltage to a lower (or higher) DC voltage using a circuit topology called DC-DC converter. As many electronic devices are sensitive to size and efficiency of the power conversion circuit, new power converters can provide relatively higher efficiency and lower size for the new electronic devices.

### SUMMARY

In some embodiments, an electronic component is disclosed. The electronic component includes: a base; a first semiconductor device attached to the base and having: a first Gallium nitride (GaN)-based switch having a first gate, a first source and a first drain, wherein the first gate is arranged to control a current flow between the first source and the first drain; a second GaN-based switch having a second source, a second gate and a second drain, wherein the second gate is coupled to the first gate and the second drain is coupled to the first drain; a second semiconductor device attached to the base and having: a logic circuit coupled to the second source and arranged to detect a magnitude of the current flow; and a driver circuit coupled to the first and second gates, the driver circuit arranged to control on and off states of the first and second GaN-based switches; and an electrically insulative encapsulant at least partially encapsulating the base, the first semiconductor device and the second semiconductor device.

In some embodiments, the electronic component further includes a first external terminal coupled to the first drain, a second external terminal coupled to the first source, and a third external terminal coupled to the logic circuit, the third external terminal arranged to transmit a signal corresponding to the detected magnitude of the current flow.

In some embodiments, the electronic component further includes a resistor coupled to the second source and wherein the logic circuit detects a voltage drop across the resistor that is proportional to the magnitude of the current flow.

In some embodiments, the resistor is disposed within the second semiconductor device.

In some embodiments, the driver circuit synchronously controls on and off states of the first and the second GaN-based switches.

In some embodiments, the electronic component further includes a fourth external terminal coupled to the logic circuit, wherein the fourth external terminal is arranged to receive pulse width modulated signals.

In some embodiments, the electronic component further includes a fifth external terminal, the fifth external terminal arranged to receive a power supply.

In some embodiments, an electronic component is disclosed. The electronic component includes: a first semiconductor device including: a first Gallium nitride (GaN)-based switch having a first gate, a first source and a first drain, wherein the first gate is arranged to control a current flow between the first source and the first drain; a second GaN-based switch having a second source, a second gate and a second drain, wherein the second gate is coupled to the first gate and the second drain is coupled to the first drain; a second semiconductor device including: a driver circuit coupled to the first and second gates, the driver circuit arranged to control on and off states of the first and second GaN-based switches; a logic circuit arranged to: detect a magnitude of the current flow via a first signal received from the second source; and control the driver circuit to turn off the first and second GaN-based switches when the detected magnitude of the current flow exceeds a threshold current value; and an electrically insulative encapsulant at least partially encapsulating the first semiconductor device and the second semiconductor device; a first external terminal disposed at an exterior surface of the electronic component and coupled to the first drain; and a second external terminal disposed at the exterior surface of the electronic component and coupled to the first source.

In some embodiments, a method of operating an electronic component is disclosed. The method includes receiving an input signal at a first external terminal; transmitting the input signal to a driver circuit disposed on a first semiconductor device disposed within the electronic component, wherein the driver circuit transmits first and second drive signals in response to receiving the input signal; transitioning a first Gallium nitride (GaN)-based switch between a first on state and a first off state in response to receiving the first drive signal, wherein the first GaN-based switch is disposed on a second semiconductor device disposed within the electronic component and wherein the first GaN-based switch controls a flow of a current between a second external terminal of the electronic component and a third external terminal of the electronic component; transitioning a second Gallium nitride (GaN)-based switch between a second on state and a second off state in response to receiving the second drive signal, wherein the second GaN-based switch is disposed on the second semiconductor device; detecting a magnitude of the current via a detection circuit disposed on the second semiconductor device, wherein the detection circuit is coupled to the second GaN-based switch; and generating an output signal at a fourth external terminal, wherein the output signal corresponds to the magnitude of the current.

In some embodiments, the detection circuit includes a resistor disposed within the first semiconductor device, the resistor being coupled to the fourth external terminal.

In some embodiments, the method further includes detecting a direction of the current via the detection circuit.

In some embodiments, the generated output signal corresponds to the magnitude and the direction of the current.

### BRIEF DESCRIPTION OF THE DRAWINGS

FIG. 1A illustrates a schematic of a PFC converter using a reduced pin count controller IC, according to some embodiments; FIG. 1B illustrates a diagram of an integrated GaN power device that includes a PFC controller IC and a GaN switch, according to some embodiments;

FIG. 2A illustrates a schematic of an internal circuits of the PFC controller IC of FIG. 1A, according to some embodiments;

FIG. 2B illustrates a schematic of internal circuits of a PFC controller IC, according to certain embodiments;

FIG. 3 shows a schematic similar to the schematic of the PFC converter of FIG. 1A with some specific component values, according to certain embodiments;

FIG. 4 illustrates a schematic of a PFC converter using a reduced pin count controller IC using a capacitive sensing scheme, according to some embodiments;

FIG. 5 shows simulation results for using the equations illustrating the operation of the PFC of FIG. 4;

FIG. 6 is a simplified flowchart illustrating a method of operating a PFC converter of FIG. 1A, according to some embodiments;

FIG. 7 is a simplified flowchart illustrating a method of operating a PFC converter of FIG. 4, according to some embodiments;

FIG. 8A illustrates an integrated GaN power device 800 according to an embodiment of the disclosure. FIG. 8B illustrates an integrated GaN power device in a four-terminal DPAK package according to an embodiment of the disclosure. FIG. 8C illustrates an integrated GaN power device 850 according to an embodiment of the disclosure;

FIGS. 9A-9C show outside views of a surface-mount semiconductor package including a controller and a power switch, according to some embodiments;

FIGS. 9D-9F show outside views of a surface-mount semiconductor package with a high-voltage pin on the right, the surface-mount semiconductor package including a controller and a power switch, according to some embodiments;

FIGS. 9G-9I show outside views of a surface-mount semiconductor package with top cooling, the surface-mount semiconductor package including a controller and a power switch, according to some embodiments;

FIGS. 10A-10C show outside views of a through-hole semiconductor package including a controller and a power switch, according to some embodiments;

FIGS. 10D-10F show outside views of a through-hole semiconductor package with encapsulated back pad, the package including a controller and a power switch, according to some embodiments;

FIGS. 10G-10I show outside views of a through-hole semiconductor package with high-voltage pin on the right, the package including a controller and a power switch, according to some embodiments;

FIGS. 11A-11B show outside views of a surface-mount semiconductor package with a slot, the package including a controller and a power switch, according to some embodiments;

FIGS. 11C-11D show outside views of a surface-mount semiconductor package with a slot with high-voltage pin on the right, the package including a controller and a power switch, according to some embodiments;

FIGS. 12A-12B show outside views of a through-hole semiconductor package with a slot, including a controller and a power switch, according to some embodiments;

FIGS. 12C-12D show outside views of a through-hole semiconductor package with a slot and encapsulated on back, including a controller and a power switch, according to some embodiments;

FIGS. 12E-12F show outside views of a through-hole semiconductor package with a slot with the high-voltage pin on the right, including a controller and a power switch, according to some embodiments;

FIG. 13A shows an inside view of a surface-mount package including a controller and a power switch, according to some embodiments. FIG. 13B illustrates a diagram of an integrated GaN power device that includes a driver circuit and a GaN switch, according to some embodiments. FIG. 13C illustrates a diagram of an integrated GaN power device of FIG. 13B along with a controller, according to some embodiments. FIG. 13D shows a package bottom view of the package illustrated in FIG. 13A, according to some embodiments;

FIG. 14 shows an inside view of a through-hole semiconductor package having a controller and a power switch, according to some embodiments;

FIG. 15 shows an inside view of a surface-mount semiconductor package having a QR flyback controller and a power switch, according to some embodiments;

FIG. 16 shows an inside view of a through-hole semiconductor package having a QR flyback controller and a power switch, according to some embodiments;

FIGS. 17A-17C show outside views of a surface-mount semiconductor package including a controller and a power switch, according to certain embodiments;

FIGS. 18A-18B show outside views of a surface-mount semiconductor package with a slot, the surface-mount semiconductor package including a controller and a power switch, according to some embodiments;

FIG. 19 shows a schematic of a QR flyback converter using a semiconductor package to house a GaN power switch, according to some embodiments;

FIG. 20 shows a schematic of a PFC converter using a semiconductor package to house a GaN power switch, according to some embodiments;

FIG. 21 shows a schematic of a PFC converter using a semiconductor package to house a GaN power switch with a PFC controller, according to some embodiments;

FIG. 22 shows a schematic of a QR flyback converter using an integrated GaN power device in a semiconductor package to co-package a first semiconductor device and a second semiconductor device, according to some embodiments;

FIG. 23 shows a schematic and circuit technique for determining current sense resistor value and over/under voltage operational conditions using a multifunction external terminal, according to some embodiments; and

FIG. 24 illustrates a diagram of an integrated GaN power device that includes a flyback controller IC and a GaN-based die, according to some embodiments.

### DETAILED DESCRIPTION

Circuits, devices and related techniques disclosed herein relate generally to power converters. More specifically, circuits, devices and related techniques disclosed herein relate to integrated gallium nitride (GaN) power devices including PFC controllers, QR flyback controllers, and/or primary/secondary side controllers used in power converters. In some embodiments, a PFC controller circuit with reduced pin count is disclosed. PFC controller circuits and techniques disclosed herein can include sensing methods with multiplexing a sensed voltage at a drain terminal of the PFC switch onto a feedback pin of the PFC controller IC, enabling a reduction of pin count of the controller IC. From the sensed drain terminal voltage, embodiments of the disclosure enable extraction of information about input voltage of the PFC converter (Vin), about output voltage of the PFC converter (Vout), and about the zero current instant when the PFC inductor current goes to zero. Further, a valley during quasi resonant ringing can be sensed with the disclosed multiplexing scheme. Thus, embodiments of the disclosure enable multiplexing of all this functionality onto the feedback (FB) pin of the controller IC, thereby reducing pin count and saving space.

In some embodiments, a capacitive coupling scheme can be used to sense the drain voltage of the PFC switch, where the drain voltage of the PFC switch can be transmitted and multiplexed to a feedback (FB) pin of the controller IC. In various embodiments, an inductive coupling scheme can be used, the auxiliary winding may be coupled to the boost inductor and used to inject an AC signal derived from the boost inductor on top of the feedback (FB) pin voltage. In some embodiments, the controller IC can include various protection detection circuit to keep the power converter in its safe operating area as summarized here and described in more detail below.

In some embodiments, the PFC controller IC can be co-packaged with a GaN power switch in a semiconductor package to form an integrated GaN power device where the integrated GaN power device can have reduced pin count and can be utilized in PFC converter circuits. In various embodiments, the integrated GaN power device may have, for example, 5 terminals. In some embodiments, circuits and methods are disclosed for operating PFC converters that utilized gallium nitride (GaN) and/or silicon carbide (SiC) power switches, where the PFC converter may have a relatively high operational frequency. In various embodiments, the controller IC can be formed in silicon, silicon-carbide, GaN or any other suitable semiconductor material. In various embodiments, the integrated GaN power device can be used in high current and/or high voltage power conversion applications such as, but not limited to, AC to DC converters, and applications such as solar power conversion, automotive and battery charging applications.

In some embodiments, an integrated GaN power device may include a primary side controller and a main GaN-based switch, where the integrated GaN power device can be used in the primary side of a flyback converter and/or in a quasi-resonant (QR) flyback converter. Circuits and techniques disclosed herein enable co-packaging a QR flyback controller IC with a GaN-based switch in a reduced pin semiconductor package, for example, but not limited to, a DPAK-4L package. In some embodiments, the circuits on the silicon die may be arranged to detect gate drive signal, current sense information, temperature, and various other operating parameters, and generate protection signals for the GaN-based power switch. Additionally, the silicon die may be electrically coupled to the low-voltage signal pins through wire bonds and/or clips to get power supply, gate drive signal, current sense information, over-current and over-temperature protection, enable, or various other signals.

In various embodiments, an integrated GaN power device may include a secondary side controller and a synchronous rectifier GaN-based switch, where the integrated GaN power device can be used in the secondary side of a flyback converter and/or a quasi-resonant (QR) flyback converter. The integrated GaN power device may use a semiconductor package to co-package a GaN-based switch with a controller, where the package can be relatively simpler with reduced pins and reduced external components. Thermal performance may be better than comparable quad flat no-lead (QFN) packages. Further, the disclosed integrated GaN power device can be used in power conversion applications with relatively wider power ranges. Moreover, the disclosed integrated GaN power device package can be suitable for the wave soldering processes.

In some embodiments, the integrated GaN power devices can include current sensing, and various protection features inside a semiconductor package. The integrated GaN power devices can enable reduction of printed circuit board (PCB) size and enable increased operational efficiency of the power converter. In current approaches using QFN or similar packages, external pins may be used for current sensing, gate drive and power supply pin. Additionally, external pins may be used for the internal voltage regulator output and/or switching speed adjustment. Thus, in current approaches packaging cost can be relatively high. Further, in current approaches reflow soldering process may be used that can have relatively high costs, thus increasing system production costs.

In some embodiments, the semiconductor package can be a surface-mount package that can include a high-voltage pin, one or more low-voltage pins, and an exposed metal die pad on the back of the package. The high-voltage pin and the metal die pad on the back of the package can be power pins, and the low-voltage pins can be signal pins. The functions of the signal pins can be, but is not limited to, power supply, gate drive, current sense, over-current protection, over-temperature protection, and/or enable. In various embodiments, a minimum distance of 1 mm gap may be used between the high voltage pin and the adjacent low voltage pin.

In some embodiments, the disclosed semiconductor packages can be through-hole packages that can include a high voltage power pin, a low voltage power pin, and one or more low voltage signal pins. The metal die pad on the back of the package can be exposed or encapsulated with encapsulant material. In various embodiments, a minimum distance of 1 mm gap may be used between the high voltage pin and the adjacent low voltage pin. The functions of the signal pins can be, but is not limited to, power supply, gate drive, current sense, over-current protection, over-temperature protection, and/or enable. In some embodiments, a slot can be added between the high-voltage pin and the low-voltage pin to increase high-voltage creepage distance.

In various embodiments, the semiconductor package can be used for integrating one or more dies having high-voltage power switches and one or more silicon dies with control circuits having protection features. A drain terminal of the high-voltage power switch may be electrically coupled to a high-voltage pin of the semiconductor package through one or more wire bonds and/or clips, and the source may be electrically coupled to the metal die pad or low-voltage pin through one or more wire bonds or clips. The silicon die may be electrically coupled to the die of high-voltage power device through wire bonds and/or clips. The circuits on the silicon die can detect gate drive signal, current sense information, temperature, and various other operating parameters, and generate protection signals for the high-voltage power switch. Additionally, the silicon die may be electrically coupled to the low-voltage signal pins through wire bonds and/or clips to get power supply, gate drive signal, current sense information, over-current and over-temperature protection, enable, or various other signals.

Embodiments of the disclosure may be used for co-packaging of a high voltage power switch and a controller IC. A semiconductor package can integrate one or more dies having high-voltage power devices and a silicon controller die, for example, a quasi-resonant (QR) flyback converter controller IC. A drain terminal of the high-voltage power switch can be electrically coupled to a high-voltage pin of the semiconductor package through a one or more wire bonds or clips, and the source may be electrically coupled to the metal die pad or low-voltage power pin through a one or more wire bonds and/or clips. The silicon controller die can be electrically coupled to the die of the high-voltage power switch through multiple wire bonds enabling sensing/detecting of gate drive signal, current sense signal, temperature, and various other operating parameters. Additionally, the silicon controller IC die can be electrically coupled to the low-voltage signal pins through wire bonds to get power supply, feedback signal, auxiliary winding signal, current sense and various other signals.

In various embodiments, a semiconductor package can be used for providing a package for a GaN-based switch having reduced number of terminals. In some embodiments, the package may include a high voltage drain terminal, low voltage input signal terminal, a low voltage current sense terminal and a low voltage power supply terminal. A metal die pad can be used a source terminal.

In some embodiments, the disclosed semiconductor package can have a relatively low thickness, for example, a thickness lower than 2 mm. In this way, the semiconductor package may not be the thickest component on the board and may not limit the size of the enclosure. Various inventive embodiments are described herein, including methods, processes, systems, devices, and the like.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain inventive embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

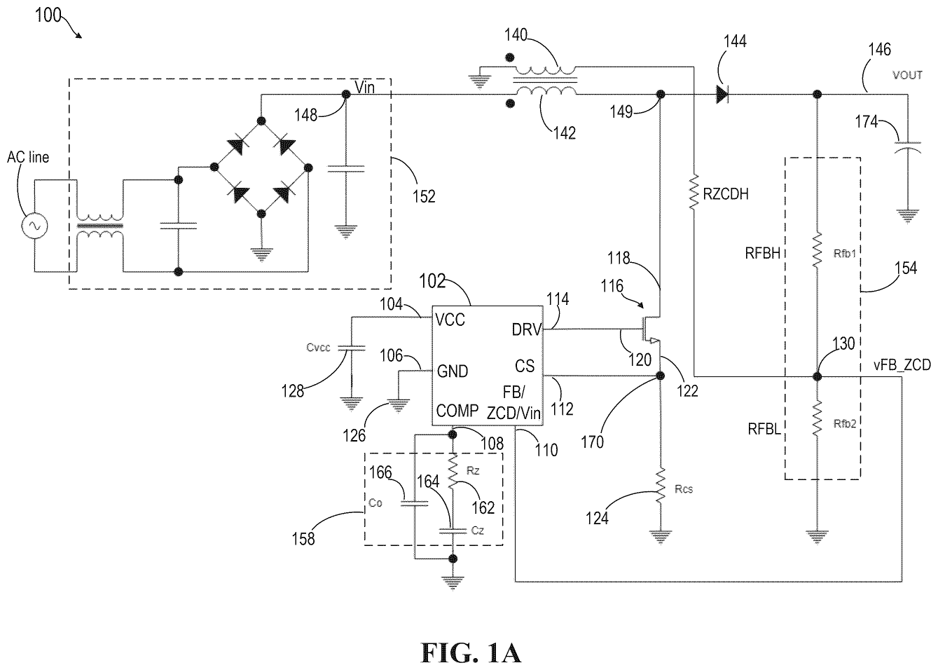

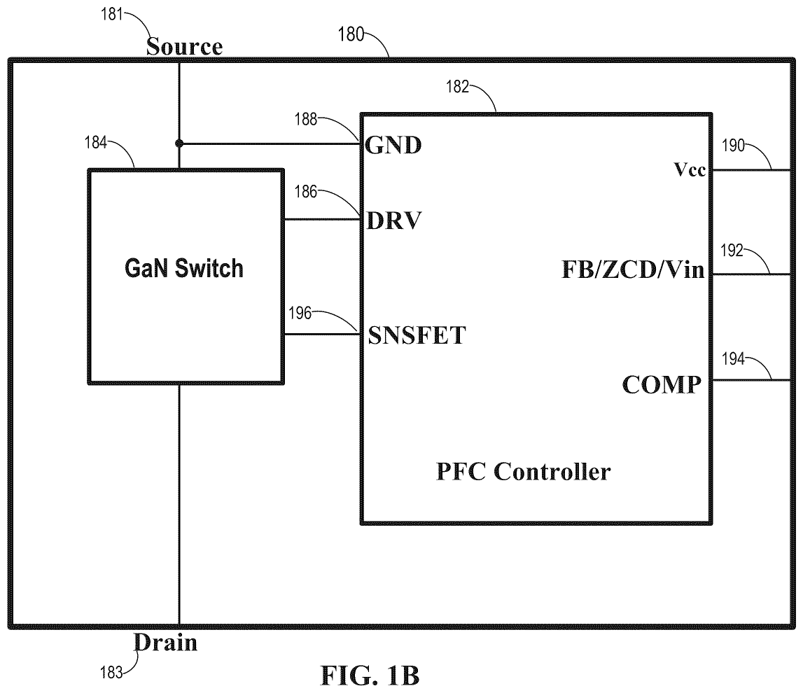

FIG. 1A illustrates a schematic of a PFC converter 100 using a reduced pin count controller IC, according to some embodiments. In FIG. 1A, an auxiliary inductor may be used to sense various current and voltages. In some embodiments, the PFC converter may be a PFC boost converter. The PFC converter 100 can include a controller IC 102. The controller IC 102 can have 6 pins including a Vcc pin 104, a GND pin 106, a COMP pin 108, a DRV pin 114, a CS pin 112 and a FB/ZCD/Vin pin 110. The PFC converter 100 can further include a switch 116, having a drain terminal 118, a gate terminal 120 and a source terminal 122. The DRV pin 114 can be coupled to the gate terminal 120 and be arranged to provide a drive signal to the gate of the switch 116 to control a conductivity state of the switch 116. The CS pin 112 can be coupled to the source terminal 122, where the source terminal 122 may be coupled to a current sense resistor 124. The CS pin 112 can be arranged to receive a signal corresponding to a current flowing through the switch 116. The GND pin can be coupled to a ground node 126.

The Vcc pin 104 can be coupled to a capacitor 128. The COMP pin 108 can be coupled to a compensation network 158 that may include a resistor 162 coupled in series to a capacitor 164, where the resistor 162 and capacitor 164 are connected in series and the combination is coupled in parallel to a capacitor 166. The FB/ZCD/Vin pin 110 can be coupled to a node 130 and can be arranged to receive a feedback signal indicating a drain voltage at the drain terminal 118, a zero current detection signal indicating when a current through a boost inductor 142 goes to zero and also Vin voltage indicating an input voltage at node 148. These signals are multiplexed onto the FB/ZCD/Vin pin 110 such that the pin count of the controller IC 102 can be reduced. The output terminal 146 can be connected to a feedback circuit 154. In some embodiments, the feedback circuit 154 can be a resistor divider that includes a first feedback resistor Rfb1 connected to a second feedback resistor Rfb2. The feedback circuit 154 can be used to sense a voltage Vout at the output terminal 146 and generate a corresponding voltage at node 130, where the corresponding voltage at node 130 can be fed back to the controller IC 102 through the FB/ZCD/Vin pin.

The PFC converter 100 can also include an auxiliary inductor 140 that is magnetically coupled to the boost inductor 142, where the auxiliary inductor 140 can be arranged to sense and generate a signal at node 130 corresponding to a value for the Vin voltage at node 148. The auxiliary inductor 140 can also generate a signal corresponding the direction of a current flowing through the boost inductor 142. The auxiliary inductor 140 can further sense a voltage at the drain terminal 118 and provide the sensed drain terminal voltage to node 130. All these information can be feedback to the controller IC 102 through the FB/ZCD/Vin pin 110.

The PFC converter 100 can also include a rectifier circuit 152. The rectifier circuit 152 can be coupled between an input AC line voltage and node 148. The rectifier circuit 152 may be arranged to provide a full wave rectified voltage Vin with filtering between the power supply mains AC line and node 148. The rectifier circuit 152 can provide I_{L} that flows through the boost inductor 142, the switch 116, and the current sense resistor 124. During operation, the switch 116 can lower the drain terminal voltage towards ground, and the boost inductor 142 may build its magnetic field and store energy as a function of I_{L}.

During operation, an AC current may create a varying magnetic flux in the boost inductor 142 that can result in a varying alternating voltage across boost inductor 142. During an on-time, the controller IC 102 may provide a positive drive voltage on the gate terminal 120 of switch 116. Thus, the switch 116 can turn on and provide a low impedance current path for the boost inductor 142. The rectifier circuit 152 can provide I_{L} that flows through boost inductor 142, the switch 116 and the current sense resistor 124. In this way, the switch 116 can lower a voltage at the drain terminal 118 towards ground, and the boost inductor 142 can builds its magnetic field and stores energy as a function of I_{L}.

During the on-time, the current sense resistor 124 can provide a voltage at node 170, the voltage being proportional to a current flowing through the switch 116. When controller IC 102 turns on the switch 116, the drain-to-source voltage of switch 116 may be relatively small. The voltage on the CS pin 112 can be equal to the voltage across the current sense resistor 124. Internal processing circuit of the controller IC 102 can compare the voltage of CS pin 112 to an overcurrent protection threshold. If the voltage of CS pin 112 exceeds the overcurrent protection threshold, the controller IC 102 may turn-off the switch 116.

During the off-time, the controller IC 102 can turn-off the switch 116, where the switch 116 can provide a high impedance current path at node 149. In response, the boost inductor 142 may resist a change in I_{L} and may operate to raise the voltage at node 149. Diode 144 may turn on and provide I_{L} to output terminal 146. Bulk capacitor 174 may store charges to smooth the output voltage across a load and may filter high frequency voltage transitions across the load.

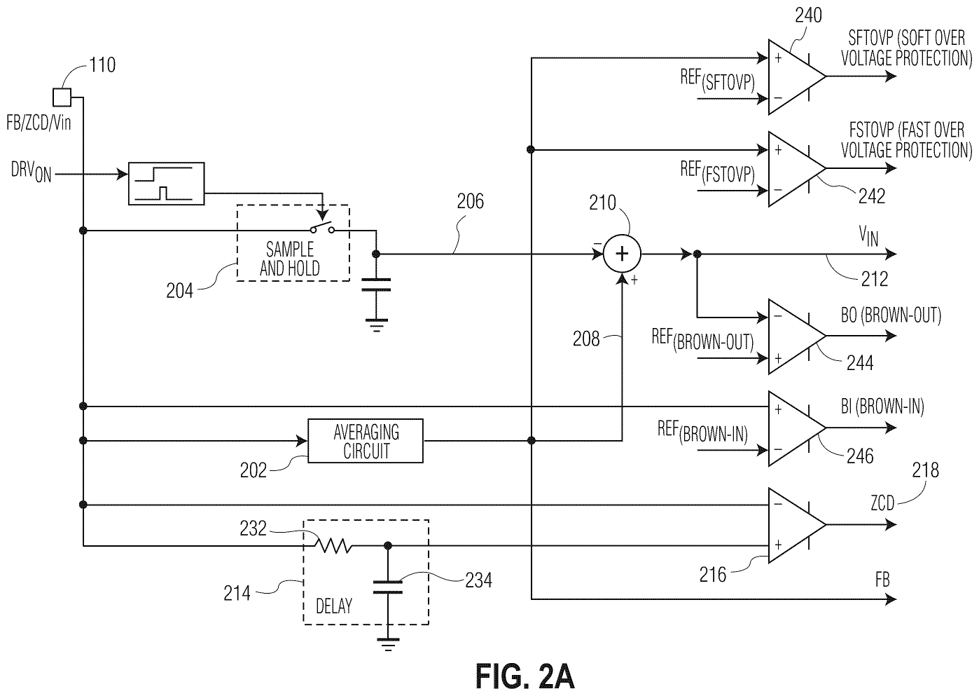

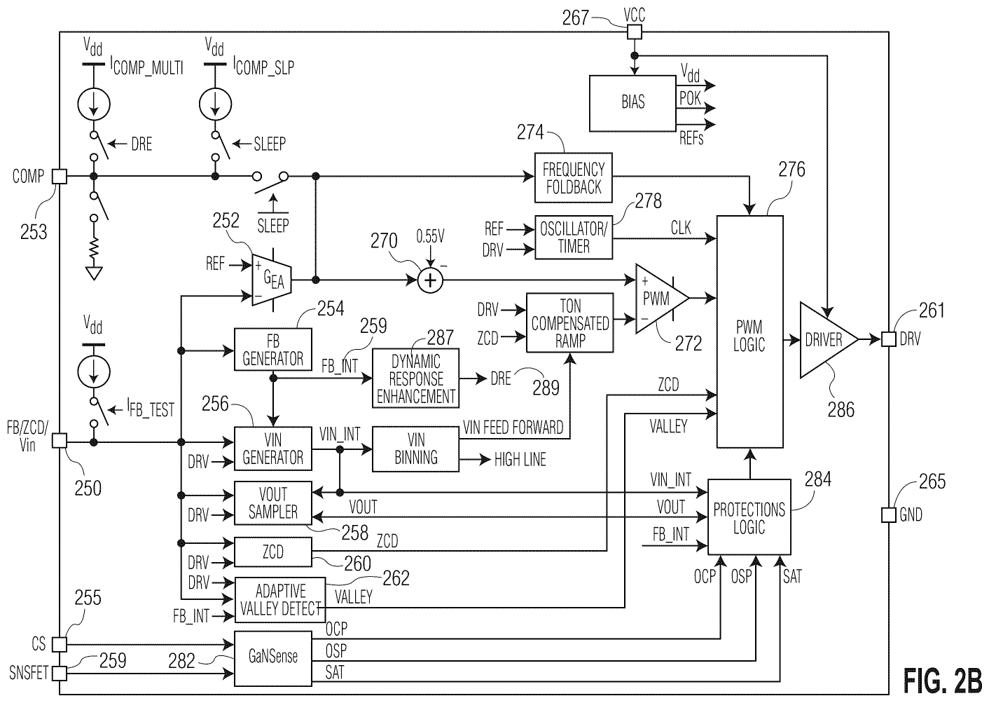

The FB/ZCD/Vin pin 110 can be arranged to operate as a multi-function input terminal to sense a variety of voltages and currents, including a feedback signal indicating a drain voltage at the drain terminal 118, a zero current detection signal indicating when a current through the boost inductor 142 goes to zero, and Vin voltage indicating an input voltage at node 148. An auxiliary inductor 140 can be magnetically coupled to the boost inductor 142, where the auxiliary inductor 140 can be arranged to inject the AC signal on top of a voltage at the FB/ZCD/Vin. The controller IC 102 may use these voltages and currents to detect several conditions including overcurrent, demagnetization phase, brownout, and overvoltage, and when a current through the boost inductor 142 goes to zero (ZCD) to adjust its operation accordingly. Details of how the internal circuits of the controller IC 102 extract all the various voltage and current information from the FB/ZCD/Vin pin will be described in more detail with respect to FIG. 2A. By using the FB/ZCD/Vin pin as a multi-function pin (pin may also be referred to as terminal), the controller IC 102 can be implemented with a reduced pin count. Thus, the PFC converter 100 can have reduced costs.

Feedback circuit 154 can receive the output voltage Vout and can provide a fraction of Vout to FB/ZCD/Vin pin 110. The fraction may be determined by the ratios of the resistors Rfb1 and Rfb2. The controller IC 102 may use the voltage on FB/ZCD/Vin pin 110 to regulate the duty cycle of the gate drive signal at the DRV pin 114. In addition, the controller IC 102 may compare the voltage at FB/ZCD/Vin pin 110 to a threshold voltage. When the voltage at FB/ZCD/Vin pin 110 goes above this threshold, the controller IC 102 may detect an overvoltage condition and turn off the drive signal to the gate terminal 120.

The controller IC 102 may use the signal at FB/ZCD/Vin pin 110 to regulate a duty cycle of the DRV signal at the DRV pin 114. The compensation network 158 can be used to adjust the regulation bandwidth for the regulation of the DRV signal at the DRV pin 114. In some embodiments, vL=Ldi/dt.

FIG. 1B illustrates a diagram of an integrated GaN power device that includes a PFC controller IC and a GaN switch, according to some embodiments. In the illustrated embodiment, a semiconductor package 180 can be used for integrating GaN-based switch 184 and a silicon-based PFC controller IC 182. The silicon-based PFC controller IC 182 can be similar to the controller IC 102 in FIG. 1A. In some embodiments, the GaN-based switch 184 may be a silicon-based or silicon carbide-based switch. The semiconductor package 180 can include a source lead 181 coupled to a source terminal of the GaN-based switch 184 and a drain lead 183 coupled to a drain terminal of the GaN-based switch 184. The PFC IC 182 may have a gate drive terminal 186 (DRV) that can be coupled to a gate terminal of the GaN-based switch 184. A ground node 188 of the PFC IC 182 may be coupled to the source terminal of the GaN-based switch 184. The semiconductor package 180 may further include a power supply lead 190 (Vcc) coupled to a power supply terminal of the PFC controller IC. Additionally, the semiconductor package 180 can include a multi-functional lead 192 that can be coupled to a multi-functional terminal (FB/ZCD/Vin) of the PFC IC. The semiconductor package 180 may also include a lead 194 coupled to a COMP terminal of the PFC controller. The PFC controller IC may have a SNSFET terminal 196 coupled to a current sense terminal of the GaN-based switch.

The SNSFET terminal 196 of the PFC controller IC may be arranged to receive a signal from the GaN-based switch 184 that is indicative of a magnitude and/or a direction of a current flowing through the GaN-based switch 184. In some embodiments, the PFC controller IC may include a current sense (CS) pin. In various embodiments, the CS pin may be left floating, while in alternate embodiments the CS may be coupled to the GaN-based switch to detect a current flowing through the GaN-based switch.

The controller IC 182 may be electrically coupled to the die of GaN-based switch 184 through wire bonds and/or clips. The circuits on the silicon die can detect gate drive signal, current sense information, temperature, and various other operating parameters, and generate protection signals for the high-voltage power switch. Additionally, the silicon die may be electrically coupled to the low-voltage signal pins through wire bonds and/or clips to get power supply, gate drive signal, current sense information, over-current and over-temperature protection, enable, or various other signals.

FIG. 2A illustrates a schematic of internal circuits of the controller IC 102, according to some embodiments. In some embodiments, the controller IC 102 may include a processing circuit. FIG. 2A illustrates circuits and techniques used to extract various information from the signals that are multiplexed onto the FB/ZCD/Vin pin 110. As shown in FIG. 2A, the FB/ZCD/Vin pin 110 may be coupled to an averaging circuit 202, and to a sampling circuit 204. In some embodiments, the sampling circuit 204 can include a sample and hold circuit. The sampling circuit 204 and the averaging circuit 202 can be both coupled to a summing circuit 210. An output of the summing circuit 210 can be coupled to a node 212. The averaging circuit 202 can provide a voltage at node 208 which corresponds to an average of the voltage on the FB/ZCD/Vin pin. During the on-time (T-on), the sampling circuit 204 can sample the voltage at the FB/ZCD/Vin pin 110 in order to get a voltage that corresponds to the Vin and provide that sampled voltage value at node 206. Subsequently, an actual value of Vin voltage can be obtained by subtracting, using the summing circuit 210, the sampled value at node 206 from the voltage value at node 208. The actual value of Vin is provided at node 212.

Using the FB/ZCD/Vin pin 110, a zero current detection (ZCD) method can be implemented to detect when the current I_{L} goes to zero. As shown in FIG. 2A, the FB/ZCD/Vin pin can further be coupled to a delay circuit 214 and to a first input of a comparator 216. In some embodiments, the delay circuit may include a resistor 232 coupled to a capacitor 234. The output of the delay circuit 214 can be coupled to a second input of the comparator 216. The comparator 216 can have an output terminal coupled to node 218. To determine when the boost inductor current goes to zero, a voltage at FB/ZCD/Vin pin 110 can be compared, using the comparator 216, to a delayed version (or a slowed version) of the voltage at FB/ZCD/Vin pin 110 to determine when the pin voltage and its delayed version diverge. At a time when the comparator 216 determines that the voltages have diverged sufficiently can be used as the instant when the inductor current has reached zero or substantially zero.

The FB/ZCD/Vin pin 110 can also be used to detect over-voltage condition on the output voltage. As shown in FIG. 2A, an output of the averaging circuit 202 can also be coupled to a comparator 240. Comparator 240 can be arranged to compare an output of the averaging circuit 202 to a first reference voltage and provide a soft overvoltage protection signal. The output of the averaging circuit 202 can also be coupled to a comparator 242. Comparator 242 can be arranged to compare an output of the averaging circuit 202 to a second reference voltage and provide a fast overvoltage protection signal. In some embodiments, a value of the first and the second reference voltages may be substantially the same. The output of the summing circuit 210 may be coupled to a comparator 244. Comparator 244 may be arranged to compare the output of the summing circuit to a third reference voltage and provide a brown out signal. In various embodiments, a value of the third reference voltage may be same as the first and/or second reference voltages. The FB/ZCD/Vin pin 110 may also be coupled to a comparator 246. Comparator 246 may be arranged to compare a voltage at the FB/ZCD/Vin pin 110 to a fourth reference voltage to provide a brown out signal. A brown out condition may be when an input voltage to the power converter drops below a predetermined threshold voltage.

Embodiments of the disclosure are advantageous in that there are no transients related to an RC charging. Further, embodiments of the disclosure enable the PFC converter to have less operational power losses. The voltage sampled from the auxiliary winding can provide real-time information and can substantially reduce computational errors.

FIG. 2B illustrates a schematic of internal circuits of the controller IC 102, according to certain embodiments. In this embodiment, the controller IC 102 can include a multifunction input terminal FB/ZCD/Vin 250, a COMP input terminal 253, a CS input terminal 255, a SNSFET input terminal 259, a DRV output terminal 261, a GND terminal 265 and a Vcc terminal 267. In some embodiments, the controller IC 102 may only include the multifunction input terminal FB/ZCD/Vin 250, the COMP input terminal 253, the CS input terminal 255, the DRV output terminal 261, the GND terminal 265, and the Vcc terminal 267. In various embodiments, the controller IC 102 may be used as a stand-alone IC with a PFC converter. In some embodiments, the controller IC 102 may be formed with all the input and output terminals, however some terminals such as the SNSFET input terminal 259 may be left floating when the controller is used as stand alone in a PFC circuit. In some embodiments, the controller IC 102 may be co-packaged in a semiconductor package with a power switch. In various embodiments, the power switch may be GaN-based, silicon-based, or silicon carbide-based. When the controller is co-packaged in a semiconductor package with a power switch, the CS input terminal may be left floating. In some embodiments, the determination of input and output terminals to be left floating can depend on the specific application and can be changed according to user settings.

The FB/ZCD/Vin input terminal 250 may be coupled to an error amplifier 252, a feed-back (FB) generator circuit 254, a Vin generator circuit 256, a Vout sampler circuit 258, a zero current detect (ZCD) circuit 260, and an adaptive valley detect circuit 262. In some embodiments, the Vout sampler circuit 258 can include a sample and hold circuit. The COMP input terminal 253 and an output node of the error amplifier 252 can be coupled to a summing circuit 270. An output node of the summing circuit 270 can be coupled to an input node of a comparator 272. In some embodiments, the comparator 272 may be an amplifier circuit. The COMP input terminal 253 may also be coupled to a frequency foldback circuit 274.

An output node of the frequency foldback circuit 274 can be coupled to a PWM logic circuit 276. An output node of the comparator 272 may be coupled to the PWM logic circuit 276. An output node of a clock generation circuit 278 may also be coupled to the PWM logic circuit 276. The CS input terminal 255 and SNSFET input terminal 259 may be coupled to a circuit 282 (GaNSense), where the circuit 282 may be arranged to generate signals for over-current protection (VOCP), over-stress protection (OSP) and saturation protection (SAT). These signals can be used to protect the power switch and to keep the power switch operating within its safe operation area (SOA). An output node of the circuit 282 may be coupled to a protection logic circuit 284, where an output node of the protection logic circuit 284 may be coupled to the PWM logic circuit 276. An output node of the PWM logic circuit 276 may be coupled to a driver circuit 286. Output nodes of the driver circuit 286 can be coupled to the DRV output terminal 261. The DRV output terminal 261 may be coupled to a gate terminal of a power switch.

The Vin generator circuit 256 may include a delay circuit, a sampling circuit, and a summing circuit. The FB generator circuit 254 may include an averaging circuit. The averaging circuit can be used to extract Vout information. The averaging circuit can provide a signal to the Vin generator circuit 256 that corresponds to an average of the voltage on the FB/ZCD/Vin input terminal 250. During the on-time (T-on), the sampling circuit can sample the voltage at the FB/ZCD/Vin input pin 250 in order to get a voltage that corresponds to the Vin. Subsequently, an actual value of Vin voltage can be obtained by subtracting the sampled value from the signal provided by Vin generator circuit 256. The actual value of Vin is provided at node VIN_INT.

Using the FB/ZCD/Vin input terminal 250, a zero current detection (ZCD) method can be employed to detect when the current I_{L} goes to zero. The FB/ZCD/Vin input terminal 250 can further be coupled to the ZCD circuit 260. The ZCD circuit may include a delay circuit and a comparator circuit. The ZCD circuit 260 can be arranged to determine when the boost inductor current goes to zero. In some embodiments, the ZCD circuit may be arranged to compare a voltage at FB/ZCD/Vin input terminal 250 to a delayed version (or a slowed version) of the voltage at FB/ZCD/Vin input terminal 250 to determine when the input voltage and its delayed version diverge. The time when the ZCD circuit determines that the voltages have diverged sufficiently can be used as the instant when the inductor current has reached zero or substantially zero.

The FB/ZCD/Vin input terminal 250 can also be used to detect over-voltage condition on the output voltage. The FB generator circuit 254 can be arranged to generate FB_INT signal 259 that can be based on the feedback (FB) signal received at the multifunction terminal 250. The FB_INT signal 259 can be transmitted to the protection logic circuit 284 and used by the protection logic circuit 284 to generate various protections such as overvoltage protection (soft overvoltage and fast overvoltage), and brown-out and brown-in. An output of the protection logic circuit 284 may be transmitted to the PWM logic circuit 276 to be processed and a generate a drive signal correspondingly. A dynamic response enhancement (DRE) circuit 287 may be arranged to receive a FB_INT signal 259 (generated by the FB generator circuit) that can be based on the feedback (FB) signal received at the multifunction terminal 250. The dynamic response enhancement (DRE) circuit 287 may be arranged to generate a signal DRE 289 that can be used by the compensation circuit (COMP) to enhance the charging speed of the compensation network that is arranged to compensate the loop.

The PWM logic circuit 276 may be arranged to receive various signals from the various circuits inside the controller IC 102. The PWM logic circuit 276 can be arranged to provide a drive signal in response to receiving a first voltage representative of a voltage proportional to an output voltage of the power converter circuit at the FB/ZCD/Vin input terminal 250 and to receiving a second voltage proportional to a current flowing through the auxiliary inductor 140.

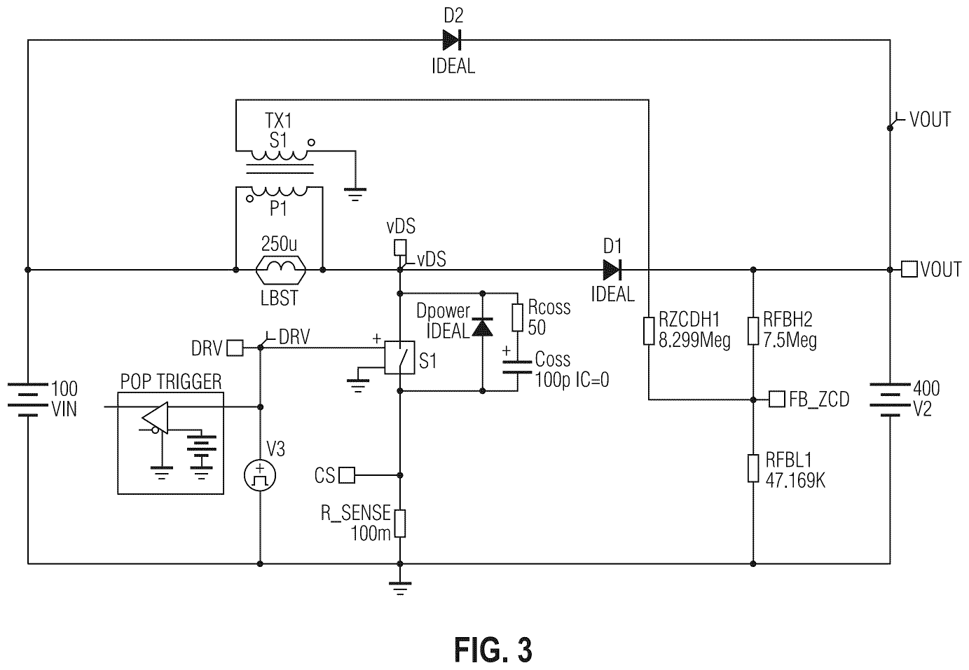

FIG. 3 shows a schematic similar to the schematic of FIG. 1A with some specific component values, according to certain embodiments. In the illustrated embodiment, below equations can be used to derive VFB ZCD:

$${{vFB\_ZCD = VOUT \cdot \frac{RFBL}{RFBL + RFBH} + vL \cdot \frac{{N}_{s}}{{N}_{p}} \frac{RZCDH}{RZCDH + RFBH // RFBL} \\ \begin{matrix}〈 vL 〉 = 0 & 〈 vFB\_ZCD 〉 = VOUT \cdot \frac{RFBL}{RFBL + RFBH}\end{matrix} \\ vFB\_ZCD \vert}_{PWMON} = VOUT \cdot \frac{RFBL}{RFBL + RFBH} + ( - VIN ) \cdot \frac{{N}_{s}}{{N}_{p}} \frac{RZCDH}{RZCDH + RFBH // RFBL} \\ ( vFB\_ZCD - 〈 vFB\_ZCD 〉 ) \vert}_{PWMON} = ( - VIN ) \cdot \frac{{N}_{s}}{{N}_{p}} \frac{RZCDH}{RZCDH + RFBH // RFBL}$$

In a switching cycle, an average voltage of VFB_ZCD may be VFB, which can be used as the feedback basis for the output voltage Vout. In the PWM on-time, after subtracting the VFB voltage from VFB_ZCD, the information of the input voltage VIN can be separated. Embodiments of the disclosure can use VFB voltage level and VFB_ZCD to perform the action of switching valley switching.

During the off time, the VFB_ZCD voltage provides an instantaneous snapshot of the VOUT voltage, that can be sampled and extracted in the same way Vin is extracted. This information can be used for yet another overvoltage protection in some cases. This information is not delayed as the Averaging information is delayed so can be used for quick response Vout over voltage protection scenarios.

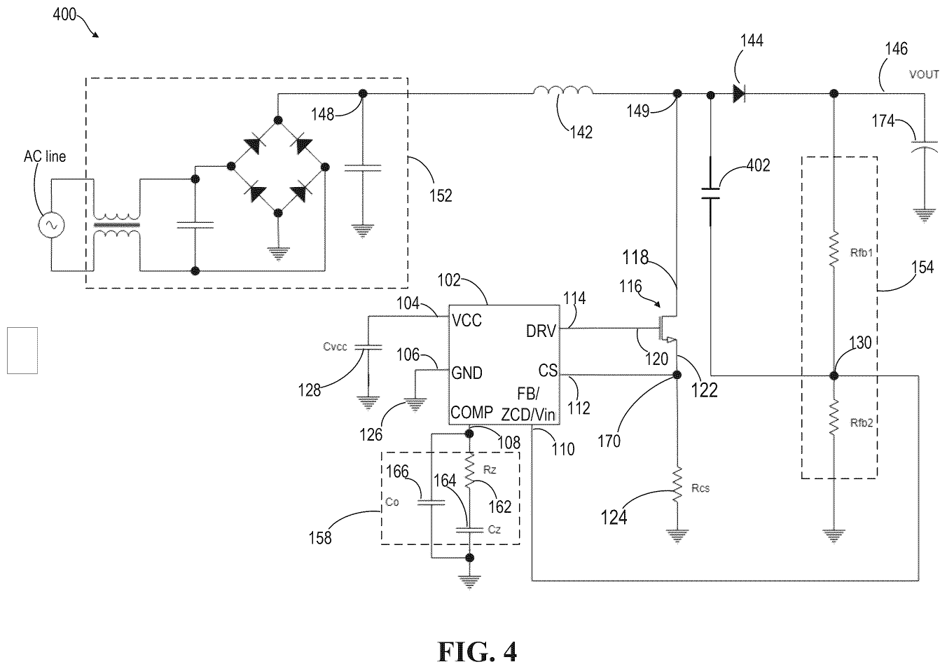

FIG. 4 illustrates a schematic of a PFC converter 400 using a reduced pin count controller IC using a capacitive sensing scheme, according to some embodiments. FIG. 4 is similar to FIG. 1A, except instead of using an auxiliary winding, a sensing capacitor 402 may be used to sense a voltage at the drain terminal of the switch 116 and transmit the sensed voltage to the FB/ZCD/Vin pin 110. In the illustrated embodiment, the following equations can be used to determine the value for VFB_ZCD:

$${vFB\_ZCD = VOUT \cdot \frac{RFBL}{RFBL + RFBH} + {vDS}_{AC} \frac{RFBH // RFBL}{RZCDH + RFBH // RFBL} \\ \begin{matrix}{vDS}_{AC} = vDS - VIN & 〈 {vDS}_{AC} 〉 = 0\end{matrix} \\ {vDS}_{AC} \vert}_{PWMON} = 0 - VIN = - VIN$$

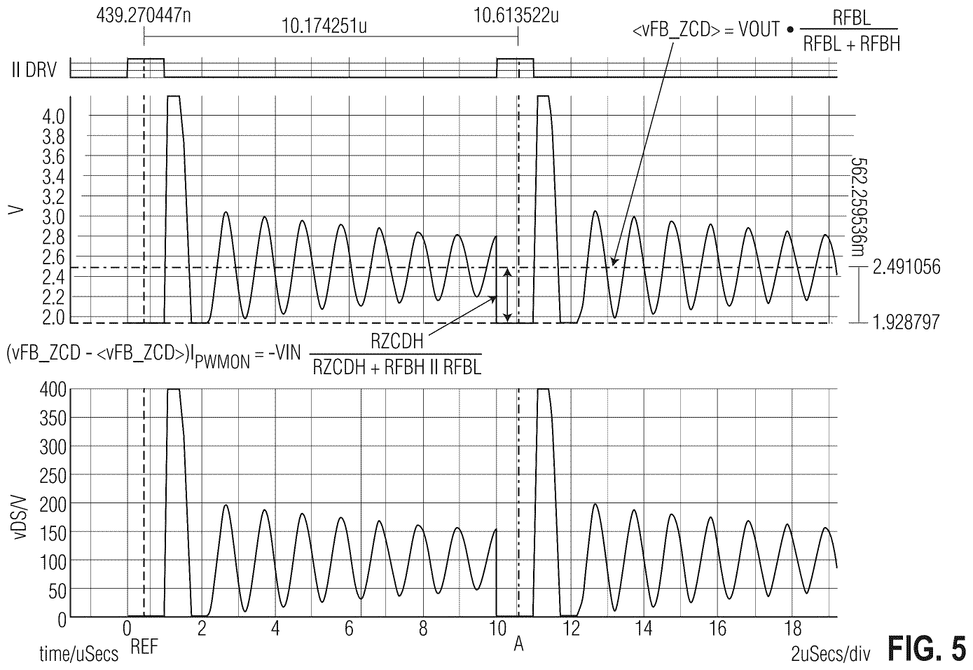

FIG. 5 shows simulation results for using the above equations. The blue waveform shows the FB_ZCD node waveform while the red waveform shows the voltage on the drain of the switch 116. The blue waveform marks the average voltage by a blue dotted line centered at 2.5V. During the ON time the dual green arrow shows the dip in the blue waveform and the delta from the average shows the magnitude is proportional to Vin.

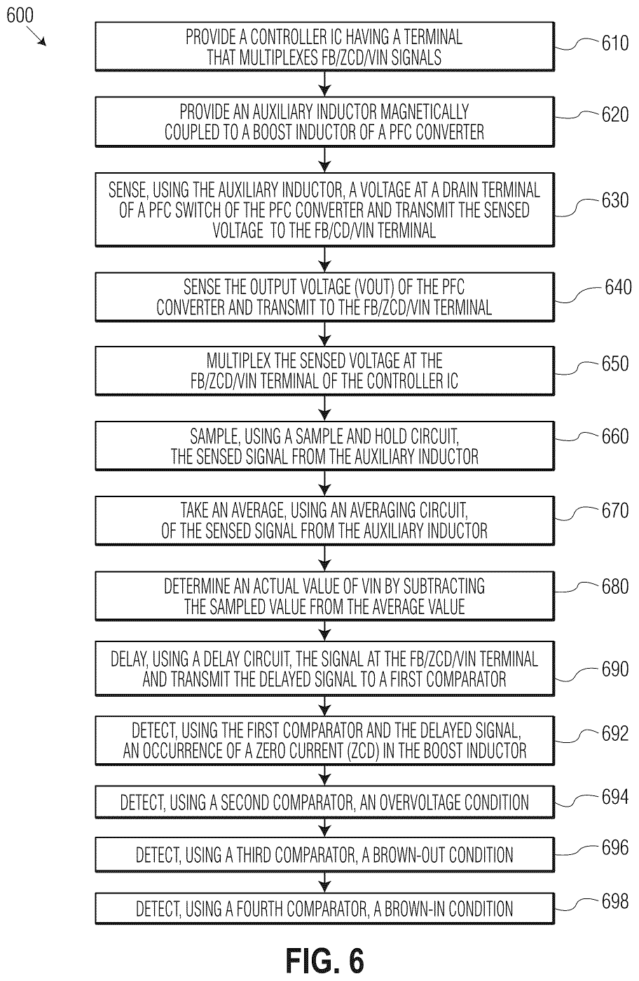

FIG. 6 is a simplified flowchart illustrating a method 600 of operating a PFC converter 100 having a controller IC 102, according to some embodiments. Referring to FIGS. 1-2 and FIG. 6, the method 600 includes provide a controller IC having a terminal that multiplexes FB/ZCD/Vin signals (610). The method also includes provide an auxiliary inductor magnetically coupled to a boost inductor of the PFC converter (620). The method additional includes sensing, using the auxiliary inductor, a voltage at a drain terminal of a switch of the PFC converter and transmitting the sensed voltage to the FB/CD/Vin terminal of the controller IC (630). The method further includes sensing the output voltage (Vout) of the PFC converter and transmitting that sensed voltage to the FB/ZCD/Vin terminal (640). The method also includes multiplex the sensed output voltage and the signal from the auxiliary inductor at the FB/ZCD/Vin terminal of the controller IC (650). Further, the method includes sampling, using a sample and hold circuit, the sensed signal from the auxiliary inductor (660). The method also includes taking an average of the sensed signal from the auxiliary inductor using an averaging circuit (670). The method additionally includes determining an actual value of Vin by subtracting the sampled value from the average value (680). The method also includes delaying, using a delay circuit, the signal at the FB/ZCD/Vin terminal and transmitting the delayed signal to a first comparator (690). The method further includes detecting, using the first comparator and the delayed signal, an occurrence of a zero current (ZCD) in the boost inductor (692). The method additionally includes detecting, using a second comparator, an overvoltage condition (694). The method additionally includes detecting, using a third comparator, a brown-out condition (696). The method further includes detecting, using a fourth comparator, a brown-in condition (698).

It should be appreciated that the specific steps illustrated in FIG. 6 provide a particular method of operating a PFC converter circuit having a controller IC according to an embodiment of the disclosure. Other sequences of steps may also be performed according to alternative embodiments. For example, alternative embodiments of the disclosure may perform the steps outlined above in a different order. Moreover, the individual steps illustrated in FIG. 6 may include multiple sub-steps that may be performed in various sequences as appropriate to the individual step. Furthermore, additional steps may be added or removed depending on the particular applications. One of ordinary skill in the art would recognize many variations, modifications, and alternatives.

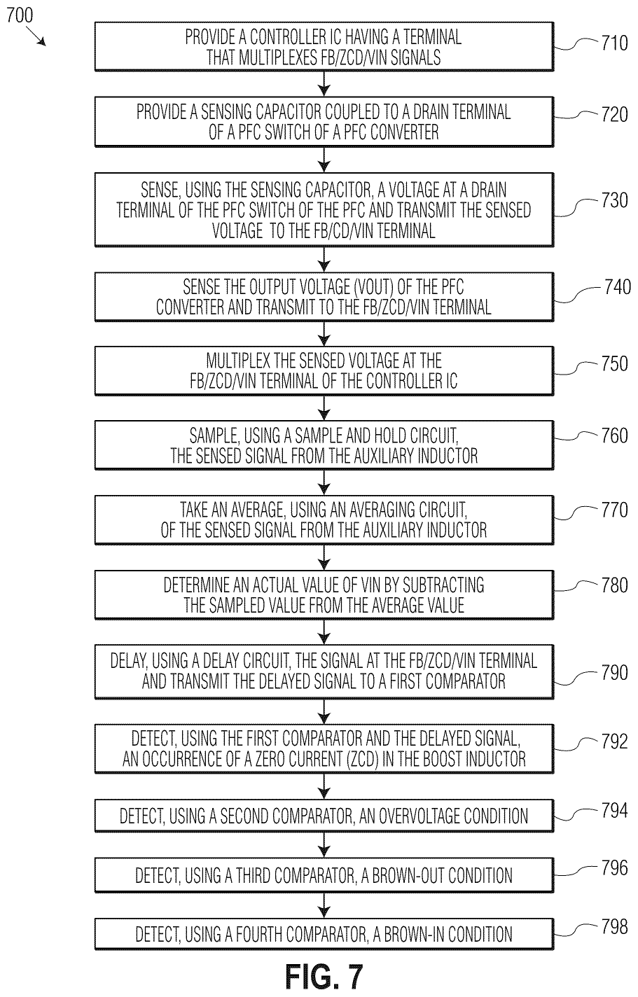

FIG. 7 is a simplified flowchart illustrating a method 700 of operating a PFC converter 400 having a controller IC 102, according to some embodiments. Referring to FIGS. 2 and 4, the method 700 includes provide a controller IC having a terminal that multiplexes FB/ZCD/Vin signals (710). The method also includes providing a sensing capacitor coupled to a drain terminal of a PFC switch of a PFC converter (720). The method additional includes sensing, using the sensing capacitor, a voltage at a drain terminal of a switch of the PFC converter and transmitting the sensed voltage to the FB/CD/Vin terminal of the controller IC (730). The method further includes sensing the output voltage (Vout) of the PFC converter and transmitting that sensed voltage to the FB/ZCD/Vin terminal (740). The method also includes multiplex the sensed output voltage and the signal from the auxiliary inductor at the FB/ZCD/Vin terminal of the controller IC (750). Further, the method includes sampling, using a sample and hold circuit, the sensed signal from the auxiliary inductor (760). The method also includes taking an average of the sensed signal from the auxiliary inductor using an averaging circuit (770). The method additionally includes determining an actual value of Vin by subtracting the sampled value from the average value (780). The method also includes delaying, using a delay circuit, the signal at the FB/ZCD/Vin terminal and transmitting the delayed signal to a first comparator (790). The method further includes detecting, using the first comparator and the delayed signal, an occurrence of a zero current (ZCD) in the boost inductor (792). The method additionally includes detecting, using a second comparator, an overvoltage condition (794). The method additionally includes detecting, using a third comparator, a brown-out condition (796). The method further includes detecting, using a fourth comparator, a brown-in condition (798).

It should be appreciated that the specific steps illustrated in FIG. 7 provide a particular method of operating a PFC converter circuit having a controller IC according to an embodiment of the disclosure. Other sequences of steps may also be performed according to alternative embodiments. For example, alternative embodiments of the disclosure may perform the steps outlined above in a different order. Moreover, the individual steps illustrated in FIG. 7 may include multiple sub-steps that may be performed in various sequences as appropriate to the individual step. Furthermore, additional steps may be added or removed depending on the particular applications. One of ordinary skill in the art would recognize many variations, modifications, and alternatives.

### PFC Controller Co-Packaged With Power Switch

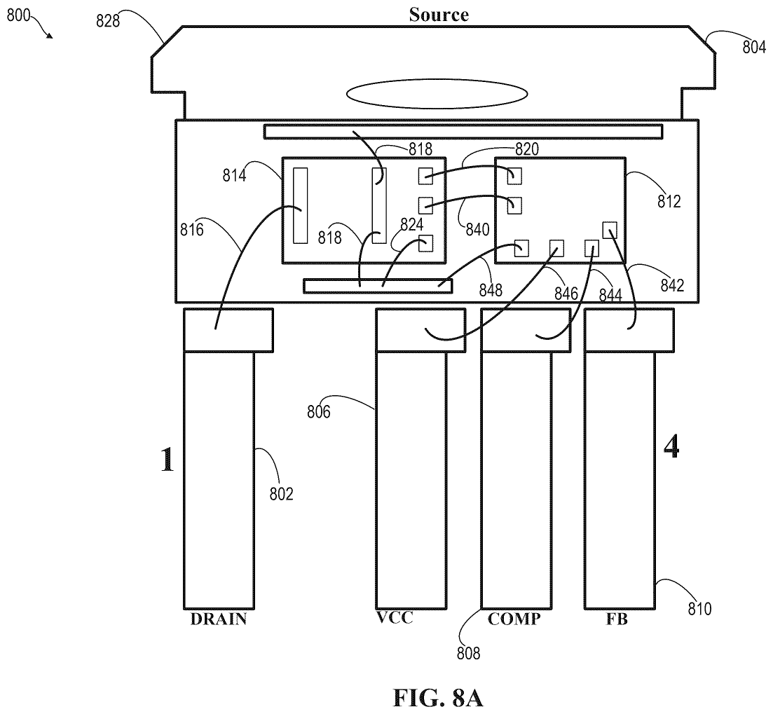

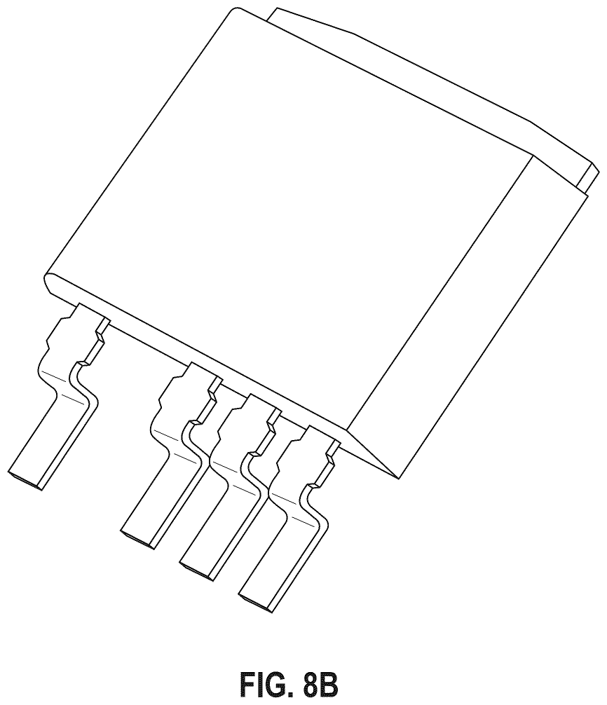

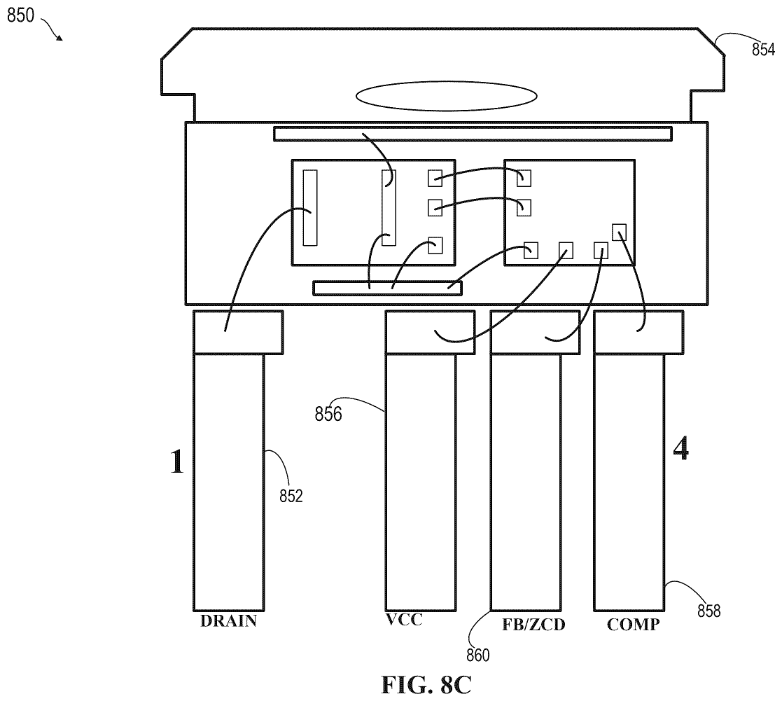

FIG. 8A illustrates an integrated GaN power device 800 according to an embodiment of the disclosure. As shown in FIG. 8A, integrated GaN power device 800 can include a GaN power transistor 814 and a controller IC 812 in a semiconductor package 828. By integrating the GaN power transistor 814 and the controller IC 812 in the semiconductor package 828, pin count can be reduced, and a majority of package parasitic elements can be eliminated, allowing the use of the integrated GaN power device 800 in high current and high-power applications. Further, the integrated GaN power device in a semiconductor package saves PCB area and can save systems costs. In some embodiments, the semiconductor package may be, for example but not limited to, a DPACK4.

The integrated GaN power device 800 can include a drain terminal 802, a source terminal 804, a Vcc terminal 806, a COMP terminal 808 and a FB terminal 810. In some embodiments, a ground node may be a back plate of the semiconductor package. A source terminal of the GaN power transistor 814 can be coupled to the source back plate via multiple wirebonds 818. A drain terminal of the GaN power transistor 814 can be coupled to the drain terminal 802 of the semiconductor package via multiple wirebonds 816. A gate terminal of the GaN power transistor 814 can be coupled to the controller IC 812 via wirebond 820. The wirebonds 820, 840 and the middle wirebond can be used for driving the gate terminal of the GaN power switch, or driving a power down FET that can hold the GaN switch gate terminal low during OFF time, or a signal that can get a supply from the gate terminal of the GaN switch during its OFF time and there can be signals from the GaN die that provide a current signal proportional to the current in the main GaN switch to perform the “current limit” functions. In various embodiments, order and/or use of these connections may vary with various configuration of GaN die. A ground node of the controller IC 812 can be connected to the same L pad on the top on the package where the source bond wires are connected. This connection can be exposed at the top right of the package.

A Vcc pin of the controller IC 812 may be coupled to the Vcc terminal 806 via wirebond 846. A COMP pin of the controller IC 812 may be coupled to the COMP terminal 808 via wirebond 844. A FB pin of the controller IC 812 may be coupled to the FB terminal 810 via wirebond 842. A ground of the controller IC 812 may be coupled to a ground of the package via wirebond 848. In the illustrated embodiment, the current sense (CS) function can be built-in (with trim option) the integrated GaN power device 800 and the current sense threshold is pretrimmed on the controller. In some embodiments, wirebond 824 may be another connection from the GaN die to the Source/GND node. In various embodiments, the wirebond 824 may be used or not used depending on the configuration of the GaN die used. In some embodiments, wirebond 824 may be used as a ground connection of any auxiliary circuitry, for example, a “power down” circuitry in the GaN die. In various embodiments, wirebond 824 may not be used. In various embodiments, wire bonds may be replaced by alternate attachment techniques.

In some embodiments, the controller IC 812 may be the same as the earlier described controller IC 102. In various embodiments, the controller IC 812 can control and drive the GaN power transistor 814. Further, the controller IC 812 can include various features for driving the GaN power transistor 814 and features to keep the GaN power transistor 814 in its safe operating area. It will be understood by those skilled in the art that the controller IC 812 can be utilized to drive GaN high electron mobility transistors (HEMT) as well as other power transistors such as, but not limited to, silicon carbide transistors, isolated gate bipolar transistors (IGBT) and silicon MOSFETs. FIG. 8B illustrates an integrated GaN power device in a four-terminal DPAK package according to an embodiment of the disclosure.

FIG. 8C illustrates an integrated GaN power device 850 according to an embodiment of the disclosure. The integrated GaN power device 850 can include a drain terminal 852, a source terminal 854, a Vcc terminal 856, a COMP terminal 858 and a FB/ZCD terminal 860. The integrated GaN power device 850 is similar to the integrated GaN power device 800, except that the pin functions are different. In the integrated GaN power device 850, the controller IC and the GaN power device may be disposed at an angle within the semiconductor package. In this way, the connecting wirebonds can be shorter, thus reducing parasitic inductances and capacitances that may be associated with wirebonds. Therefore, the integrated GaN power device 850 can operate at higher operational frequencies with relatively reduced ringing. In various embodiments, the connecting wirebonds may be replaced by other attaching techniques, such as but not limited to, copper straps and/or copper clips.

### Integrated GaN Power Device

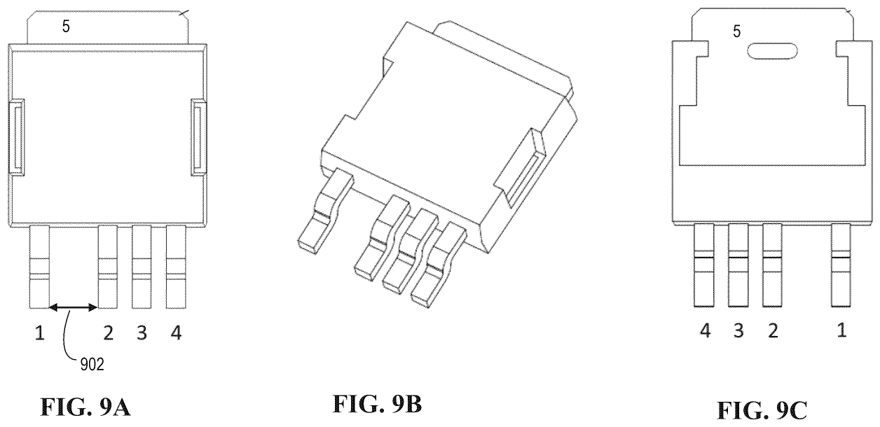

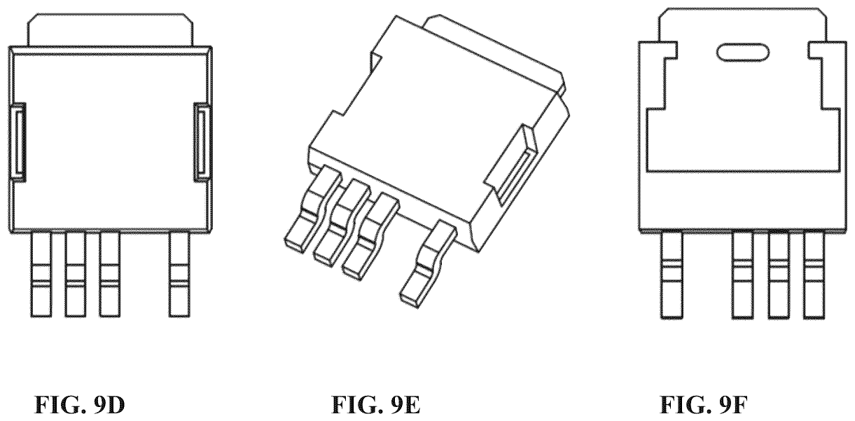

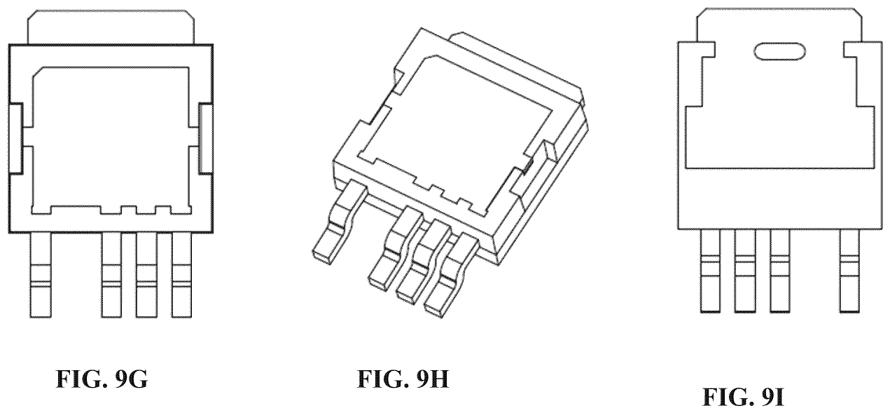

FIGS. 9A-9C show outside views of a surface-mount semiconductor package including a controller and a power switch, according to some embodiments. In some embodiments, the package may include one or more power switches. FIGS. 9A-9C illustrate a front view, a side view and a bottom view of the surface-mount package, respectively. In this embodiment, pin 1 may be a high-voltage pin, pins 2, 3 and 4 may be three low-voltage pins, and there can an exposed metal die pad 5 on the back of the package. Pin 1 and metal pad 5 on the back can be power pins, and low-voltage pins 2, 3 and 4 can be signal pins. In some embodiments, a spacing 902 between high voltage pin 1 and the low voltage pin 2 may be greater than, for example, 1 mm. In some embodiments, the spacing 902 can be, for example, 1.2 mm, while in other embodiments the spacing 902 can be between 0.8 and 1.1 mm, and in yet other embodiments the spacing can be between 0.9 and 1.05 mm. As appreciated by one of ordinary skill in the art having the benefit of this disclosure, the spacing 902 can be set to any suitable value.

FIGS. 9D-9F show outside views of a surface-mount semiconductor package with a high-voltage pin on the right, the surface-mount semiconductor package including a controller and a power switch, according to some embodiments. In some embodiments, the package may include one or more power switches.

FIGS. 9G-9I show outside views of a surface-mount semiconductor package with top cooling, the surface-mount semiconductor package including a controller and a power switch, according to some embodiments. In some embodiments, the package may include one or more power switches.

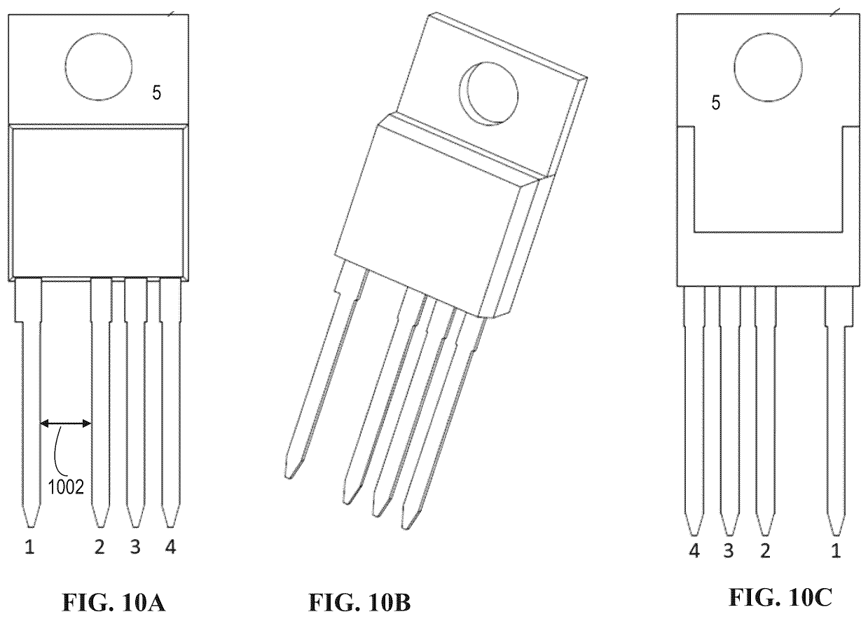

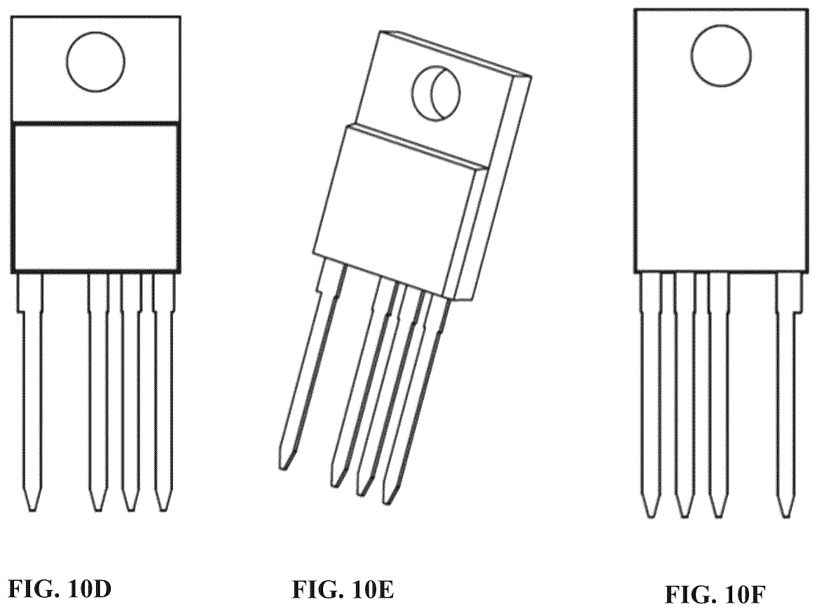

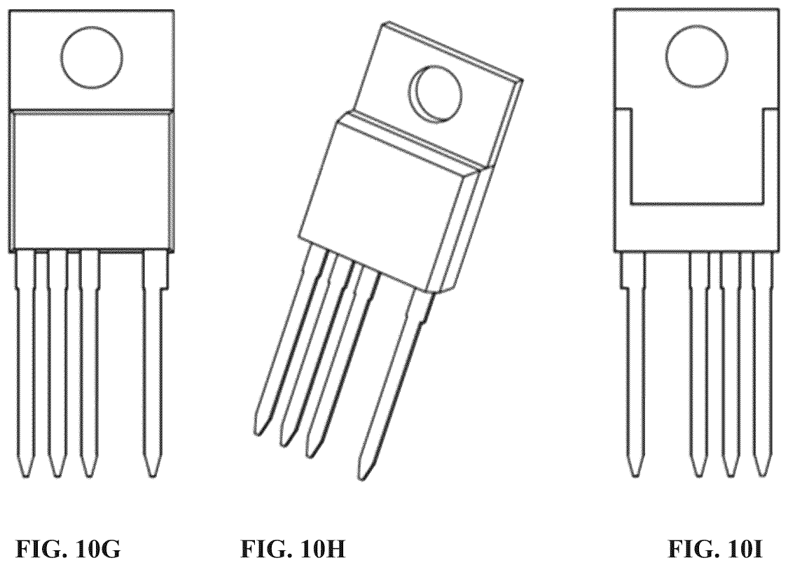

FIGS. 10A-10C show outside views of a through-hole semiconductor package including a controller and a power switch, according to some embodiments. In some embodiments, the package may include one or more power switches. FIGS. 10A-10C show a front view, a side view, and a bottom view of the package respectively. In this embodiment, pin 1 can be a high-voltage pin, and pins 2, 3 and 4 can be three low-voltage pins. There can be a metal die pad 5 on the back of the package. In some embodiments, the metal pad 5 can be exposed. In various embodiments, the metal pad 5 may be encapsulated by some encapsulant material. High-voltage pin 1 and low-voltage pin 2 can be power pins, and low-voltage pins 3 and 4 can be signal pins. In some embodiments, a spacing 1002 between high voltage pin 1 and the low voltage pin 2 may be greater than, for example, 1 mm. In some embodiments, the spacing 902 can be, for example, 1.2 mm, while in other embodiments the spacing 902 can be between 0.8 and 1.1 mm, and in yet other embodiments the spacing can be between 0.9 and 1.05 mm. As appreciated by one of ordinary skill in the art having the benefit of this disclosure, the spacing 902 can be set to any suitable value.

FIGS. 10D-10F show outside views of a through-hole semiconductor package with encapsulated back pad, the package including a controller and a power switch, according to some embodiments. In some embodiments, the package may include one or more power switches.

FIGS. 10G-10I show outside views of a through-hole semiconductor package with high-voltage pin on the right, the package including a controller and a power switch, according to some embodiments. In some embodiments, the package may include one or more power switches.

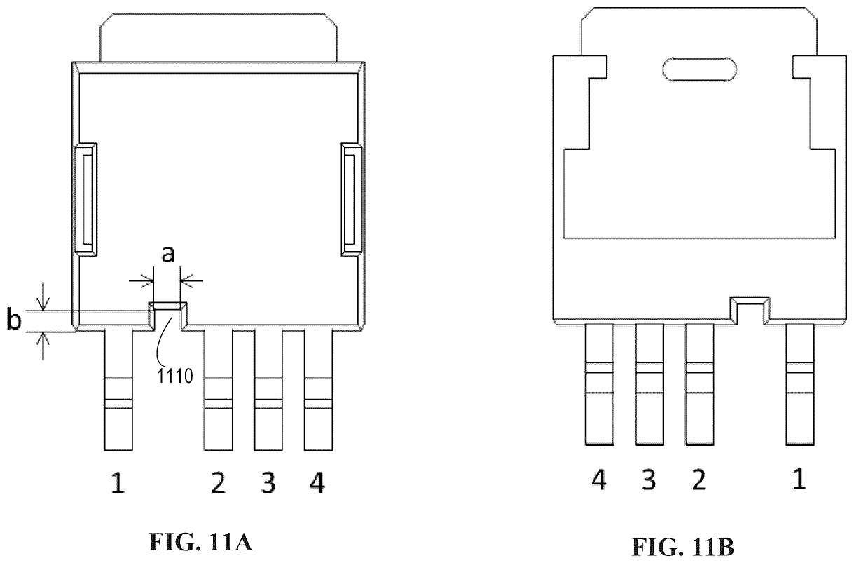

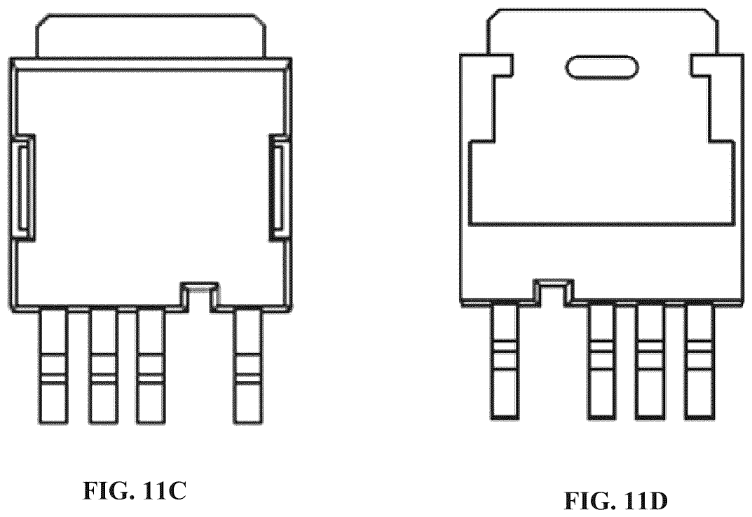

FIGS. 11A-11B show outside views of a surface-mount semiconductor package with a slot, the package including a controller and a power switch, according to some embodiments. In some embodiments, the package may include one or more power switches. FIGS. 11A-11B illustrate a front view and a bottom view of the surface-mount package with slot, respectively. This package is similar to package of FIGS. 9A-9C, except a slot 1110 with width a, and depth b is added between the high-voltage pin 1 and the low-voltage pin 2. This slot (or recess) can increase the high voltage creepage distance between high voltage and low voltage pins.

FIGS. 11C-11D show outside views of a surface-mount semiconductor package with a slot with high-voltage pin on the right, the package including a controller and a power switch, according to some embodiments. In some embodiments, the package may include one or more power switches.

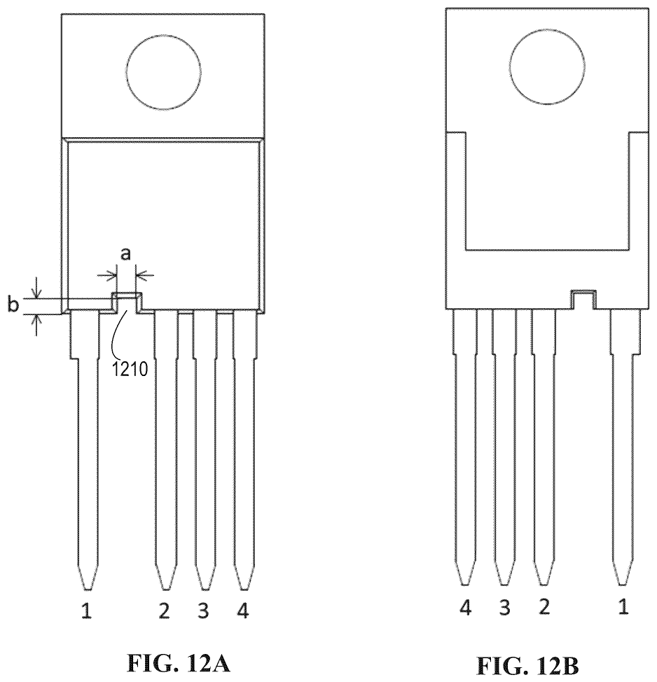

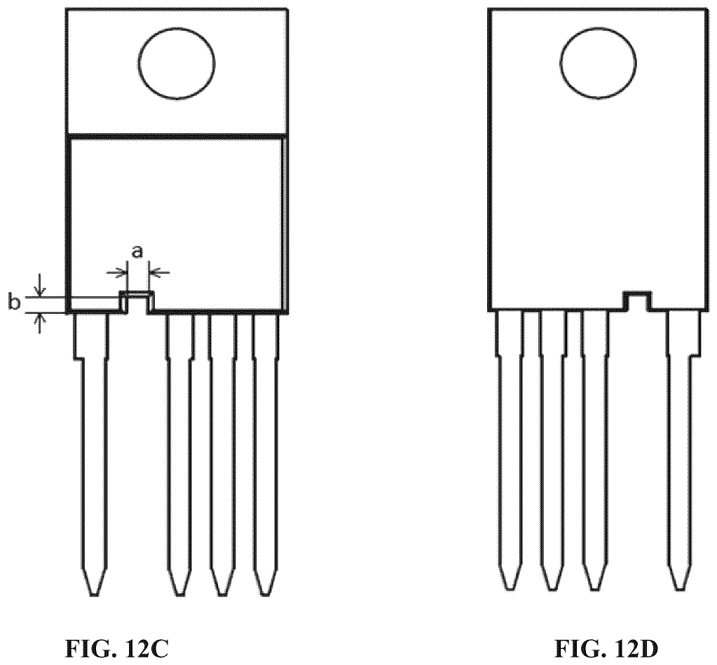

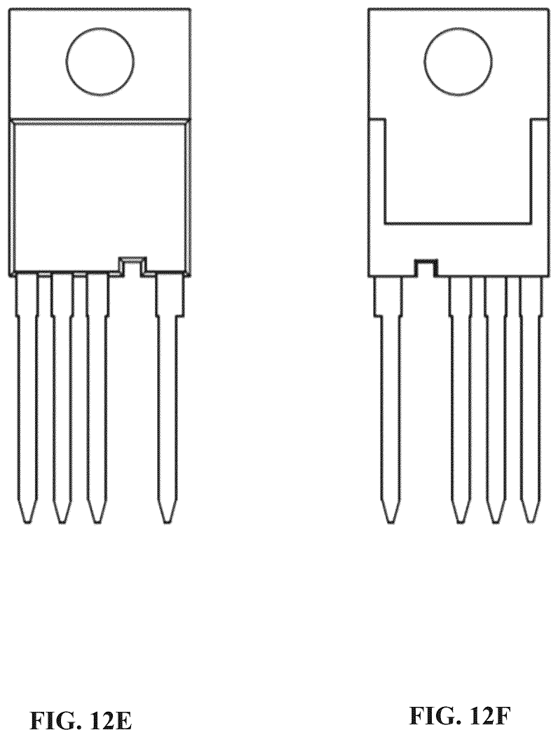

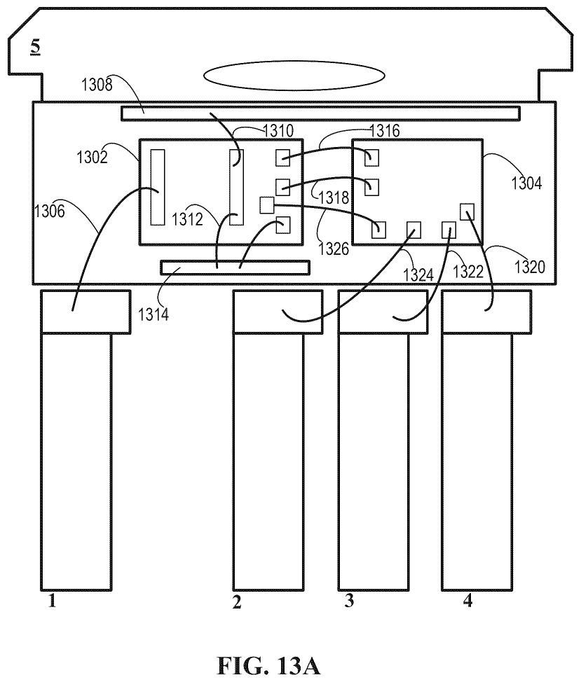

FIGS. 12A-12B show outside views of a through-hole semiconductor package with a slot, including a controller and a power switch, according to some embodiments. In some embodiments, the package may include one or more power switches. FIGS. 12A-12B show a front view, and a bottom view of the package respectively. This package is similar to package of FIGS. 10A-10B, except a slot 1210 with width a, and depth b is added between the high-voltage pin 1 and the low-voltage pin 2. This slot (or recess) can increase the high voltage creepage distance between high voltage and low voltage pins.

FIGS. 12C-12D show outside views of a through-hole semiconductor package with a slot and encapsulated on back, including a controller and a power switch, according to some embodiments. In some embodiments, the package may include one or more power switches.

FIGS. 12E-12F show outside views of a through-hole semiconductor package with a slot with the high-voltage pin on the right, including a controller and a power switch, according to some embodiments. In some embodiments, the package may include one or more power switches.

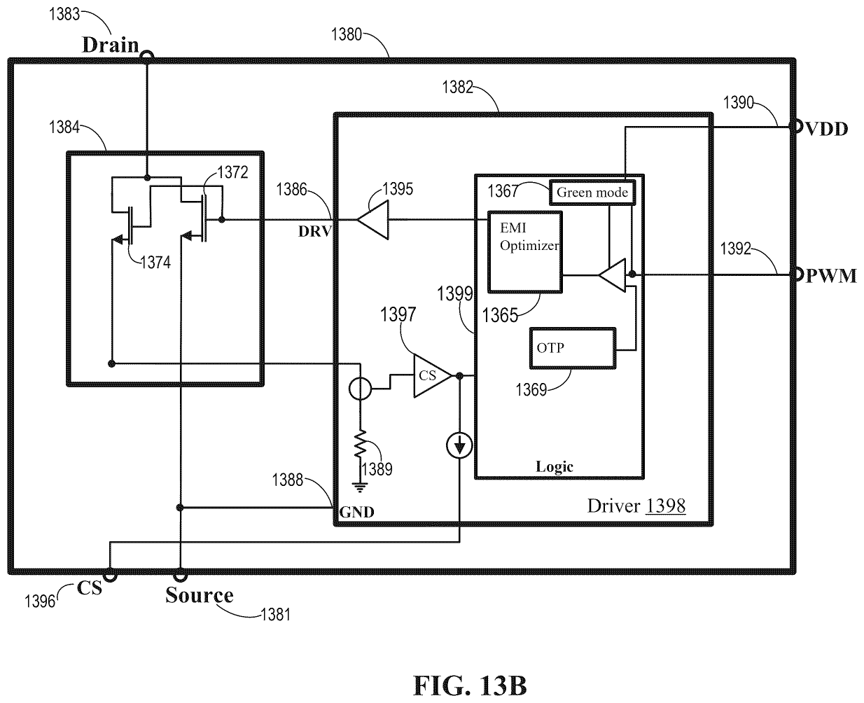

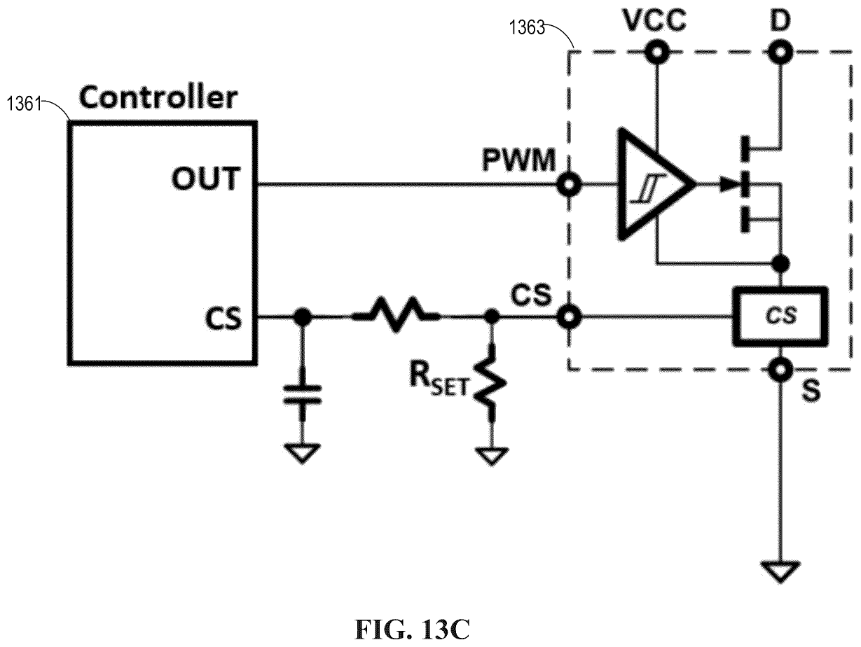

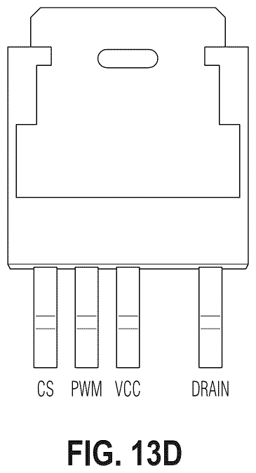

FIG. 13A shows an inside view of a surface-mount package including a controller and a power switch, according to some embodiments. In some embodiments, the package may include one or more power switches. In the illustrated embodiment, a semiconductor package is used to co-package an integrated high-voltage power switch disposed on a first semiconductor device 1302, and a second semiconductor device 1304 having a controller circuit. In some embodiments, the first semiconductor device 1302 may include a high-voltage gallium nitride (GaN)-based switch, while the second semiconductor device 1304 may be silicon-based. In some embodiments, the controller circuit may include a driver circuit. The controller circuit can integrate sampling/detection and protection functions. The first semiconductor device 1302 with the GaN-based switch can be mounted on a relatively large die pad 5 by using, for example, conductive glue. The second semiconductor device 1304 can be mounted to the die pad 5 through, for example, non-conductive glue or conductive glue. A drain terminal of the high-voltage GaN-based switch can be coupled to the high-voltage external pin 1 through one or more wire bonds 1306, or clips. The source terminal of the high-voltage GaN-based switch can be coupled to the pads 1308 and 1314 that may be plated on the die pad 5, through a one or more wire bonds 1310 and 1312, or clips. In some embodiments, the pads 1308 and 1314 may be silver plated. Low voltage external terminal 2 may be used for Vcc, low voltage external terminal 3 may be used for PWM and low voltage external terminal 4 may be used for current sense (CS) connections.

FIG. 13B illustrates a diagram of an integrated GaN power device that includes a driver circuit and a GaN switch, according to some embodiments. In the illustrated embodiment, a semiconductor package 1380 can be used for integrating a first semiconductor device 1384 and a second semiconductor device 1382. In some embodiments, the first semiconductor device 1384 can be a GaN-based die. In various embodiments, the second semiconductor device 1382 may be a silicon-based die having a driver IC 1398. The first semiconductor device 1384 can include a first GaN-based switch 1372 having a first source, a first gate and a first drain, and a second GaN-based switch 1374 having a second source, a second gate and a second drain. In some embodiments, the first gate may be coupled to the second gate and the first drain may be coupled to the second drain. In various embodiments, the first GaN-based switch may be a first transistor, and the second GaN-based switch may be a second transistor.

The semiconductor package 1380 can include an external source terminal 1381, an external drain terminal 1383, a current source (CS) terminal 1396 an external PWM terminal 1392, and an external power supply (VDD) terminal 1390. The first source can be coupled to the external source terminal 2481. The first and second drain terminals can be coupled to the external drain terminal 1383. The driver IC 1398 may have a gate drive terminal 1386 (DRV) that can be coupled to the first and second gate terminals. A ground node 1388 may be coupled to the external source terminal 1381. The external power supply terminal 1390 can be coupled to a power supply terminal of the driver IC 1398. The driver IC 1398 may have a current sense (CS) terminal 1396 coupled to the second source. The driver IC 1398 may include an over temperature protection circuit 1369, a green mode circuit 1367, and an EMI management control circuit 1365. In some embodiments, a ground node connection for the driver IC may be made to the die pad.

The CS terminal 1396 may be arranged to receive a signal from the second GaN-based switch 1374 that is indicative of a magnitude and/or a direction of a current flowing through the first GaN-based switch 1372. In some embodiments, the driver IC 1398 may include an amplifier 1397 coupled to the CS terminal. In various embodiments, A current sense resistor 1389 may be coupled between an input of the amplifier 1397 and ground. In some embodiments, the amplifier 1397 may be a comparator. An output of the amplifier 1397 may be coupled to a logic circuit 1399 that is arranged to control a signal into a driver circuit 1395. The drive circuit can be coupled to the first and second gates. In some embodiments, the CS amplifier 1397 can sense the current from the FET 1374, and correspondingly generate a proportional amplified current that can flow out of the CS external terminal 1396.

The first semiconductor device 1384 may be coupled to the second semiconductor device 1382 through wire bonds and/or clips. In some embodiments, the circuits on the second semiconductor device may be arranged to detect gate drive signal, current sense information, temperature, and various other operating parameters, and generate protection signals for the high-voltage power switch. The second semiconductor device may be electrically coupled to the low-voltage signal pins through wire bonds and/or clips.

The second semiconductor device 1304 may be coupled to first semiconductor device 1302 by one or more wire bonds 1316, 1318 and 1326, or clips. The controller circuit on the second semiconductor device 1304 may be arranged to detect a current flowing through the GaN-based switch. In some embodiments, controller circuit may be arranged to detect operating temperature or other operating parameters of the GaN-based switch. In various embodiments, the controller circuit may be arranged to transmit power supply voltage, gate drive signal, over-temperature protection signal, over-current protection signal and/or enable signal to the GaN-based switch on the first semiconductor device 1302. The second semiconductor device 1304 may be coupled to three low-voltage external pins 2, 3, and 4 through wire bonds 1324, 1322, and 1320, respectively, or clips. The external power supply voltage, gate drive signal, current sense information or other signals can be transmitted to the first semiconductor device 1302 through these three pins. The first and second semiconductor devices 1302 and 1304, respectively, and all the wire bonds can be at least partially encapsulated by an electrically insulative encapsulant. In some embodiments, the back of the die pad 5 can be exposed.

FIG. 13C illustrates a diagram of an integrated GaN power device of FIG. 13B along with a controller, according to some embodiments. In the illustrated embodiment, a controller circuit 1363 may be arranged to send PWM signals to the integrated GaN power device 1361.

FIG. 13D shows a package bottom view of the package illustrated in FIG. 13A, according to some embodiments.

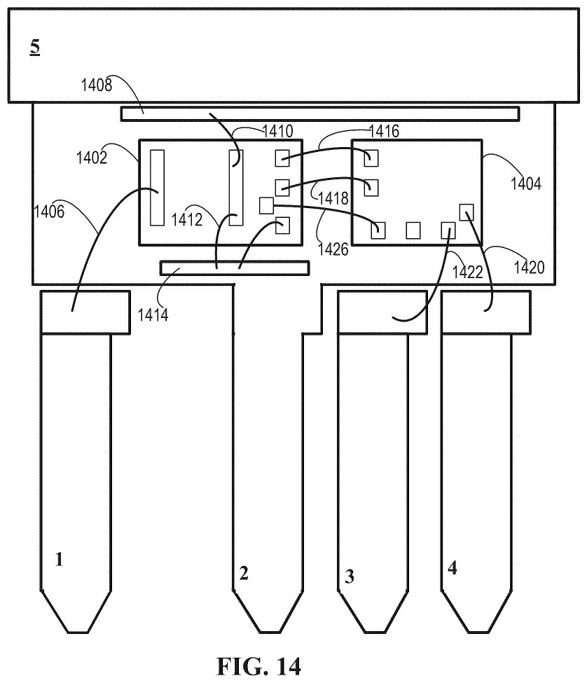

FIG. 14 shows an inside view of a through-hole semiconductor package having a controller and a power switch, according to some embodiments. In some embodiments, the package may include one or more power switches. In the illustrated embodiment, a semiconductor package is used to co-package an integrated high-voltage power switch disposed on a first die 1402, and a controller circuit disposed on a second die 1404. In some embodiments, die 1402 may include a high-voltage gallium nitride (GaN)-based switch, while die 1404 may be silicon-based. The controller circuit can integrate sampling/detection and protection functions. Die 1402 with high-voltage GaN-based switch can be mounted to a relatively large die pad 5 by using, for example, conductive glue, and die 1404 can be mounted to the die pad 5 through, for example, non-conductive glue or conductive glue. A drain terminal of the high-voltage GaN-based switch can be electrically coupled to the high-voltage pin 1 through one or more wire bonds 1406, or clips. The source terminal of the high-voltage GaN-based switch can be electrically coupled to the silver pads 1408 and 1414 that may be plated on the die pad 5 through a one or more wire bonds 1410 and 1412, or clips. In some embodiments, low voltage power pin 2 may directly connect to die pad 5. Die 1404 and the GaN-based switch may be electrically coupled by one or more wire bonds 1416, 1418 and 1426, or by clips. The controller circuit on silicon die 1404 may be arranged to detect a current, temperature, or other operating parameters of the GaN-based switch through these wire bonds, and transmit power supply voltage, gate drive signal, over-temperature protection signal, over-current protection signal and/or enable signal to the GaN-based switch on die 1402. Die 1404 may be electrically coupled to the two low-voltage pins 3, and 4 through wire bonds 1422 and 1420, respectively. The external power supply voltage, gate drive signal, current sense information or other signals can be transmitted to the die 1404 through these three pins. Die 1402, die 1404, and all the wire bonds can be at least partially encapsulated by an electrically insulative encapsulant.

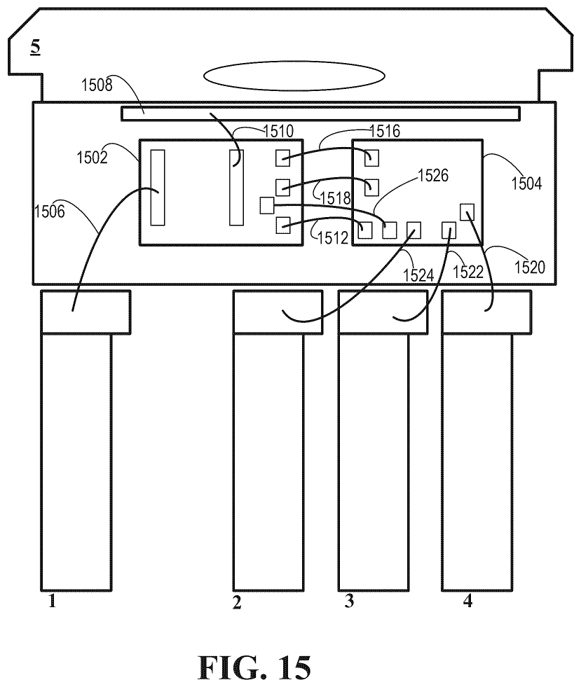

FIG. 15 shows an inside view of a surface-mount semiconductor package having a QR flyback controller and a power switch, according to some embodiments. In some embodiments, the package may include one or more power switches. In the illustrated embodiment, a semiconductor package is used to co-package an integrated high-voltage power switch disposed on a first die 1502, and a QR flyback controller circuit disposed on a second die 1504. In some embodiments, die 1502 may include a high-voltage gallium nitride (GaN)-based switch, while die 1504 may be silicon-based. The controller circuit can integrate sampling/detection and protection functions. Die 1502 with high-voltage GaN-based switch can be mounted to a relatively large die pad 5 by using, for example, conductive glue, and die 1504 can be mounted to the die pad 5 through, for example, non-conductive glue or conductive glue. A drain terminal of the high-voltage GaN-based switch can be electrically coupled to the high-voltage pin 1 through one or more wire bonds 1506, or clips. The source of the GaN-based switch can be electrically coupled to the silver pad 1508, which may be plated on the die pad 5 through one or more wire bonds 1510, or clips. In some embodiments, die 1504 and die 1502 can be electrically coupled by several single wire bonds 1512, 1526, 1518 and 1516, or by clips. Die 1504 can be arranged to detect a current, temperature, or other operating parameters of the GaN-based switch through these wire bonds, and transmit power supply voltage, gate drive signal, protection signal, or enable signal to the GaN-based switch. Die 1504 can be electrically coupled to the three low-voltage pins 2, 3, and 4 by wire bonds 1524, 1522, and 1520, respectively, or by clips. The external power supply voltage, current sense information, feedback signal, auxiliary winding voltage, or other signals can be transmitted to the Die 1504 through these three pins. Die 1502, die 1504, and all the wire bonds can be at least partially encapsulated by an electrically insulative encapsulant.

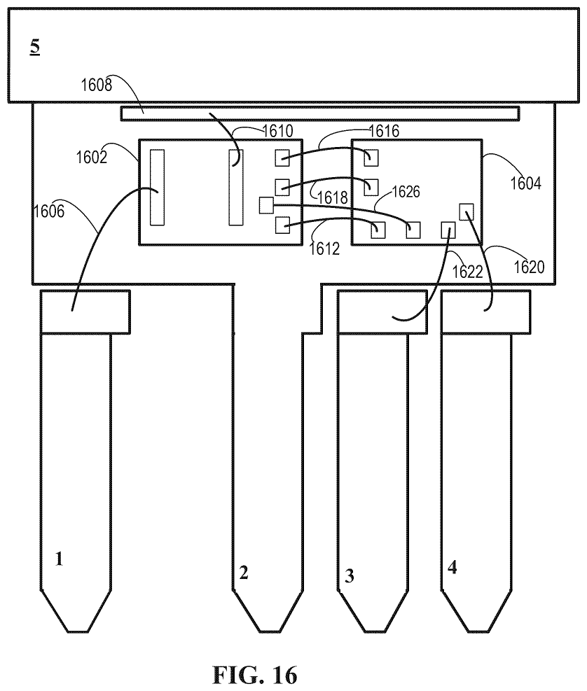

FIG. 16 shows an inside view of a through-hole semiconductor package having a QR flyback controller and a power switch, according to some embodiments. In some embodiments, the package may include one or more power switches. In the illustrated embodiment, a semiconductor package is used to co-package an integrated high-voltage power switch disposed on a first die 1602, and a QR flyback controller circuit disposed on a second die 1604. In some embodiments, die 1602 may include a high-voltage gallium nitride (GaN)-based switch, while die 1604 may be silicon-based. The controller circuit can integrate sampling/detection and protection functions. Die 1602 with high-voltage GaN-based switch can be mounted to a relatively large die pad 5 by using, for example, conductive glue, and die 1604 can be mounted to the die pad 5 through, for example, non-conductive glue or conductive glue. A drain terminal of the high-voltage GaN-based switch can be electrically coupled to the high-voltage pin 1 through one or more wire bonds 1606, or clips. The source of the GaN-based switch can be electrically coupled to the silver pad 1608, which may be plated on the die pad 5 through one or more wire bonds 1610, or clips. In some embodiments, low voltage power pin 2 may directly connect to die pad 5. Die 1604 and the GaN-based switch may be electrically coupled by one or more wire bonds 1612, 1626, 1618 and 1616, or by clips. The controller circuit on silicon die 1604 may be arranged to detect a current, temperature, or other operating parameters of the GaN-based switch through these wire bonds, and transmit power supply voltage, gate drive signal, over-temperature protection signal, over-current protection signal and/or enable signal to the GaN-based switch on die 1602. Die 1604 may be electrically coupled to the two low-voltage pins 3, and 4 through wire bonds 1622 and 1620, respectively. The external power supply voltage, gate drive signal, current sense information or other signals can be transmitted to the die 1604 through these three pins. Die 1602, die 1604, and all the wire bonds can be at least partially encapsulated by an electrically insulative encapsulant.

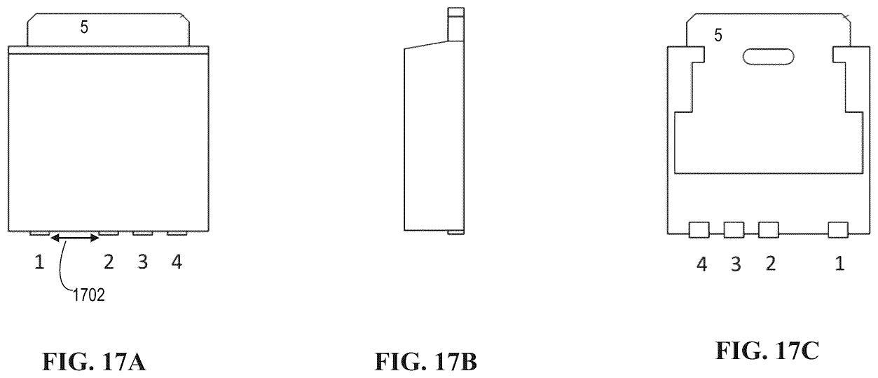

FIGS. 17A-17C show outside views of a surface-mount semiconductor package including a controller and a power switch, according to certain embodiments. In some embodiments, the package may include one or more power switches. FIGS. 17A-17C illustrate a front view, a side view and a bottom view of the surface-mount package, respectively. In this embodiment, pin 1 may be a high-voltage pin, pins 2, 3 and 4 may be three low-voltage pins, and there can an exposed metal die pad 5 on the back of the package. Pin 1 and metal pad 5 on the back can be power pins, and low-voltage pins 2, 3 and 4 can be signal pins. In some embodiments, a spacing 1702 between high voltage pin 1 and the low voltage pin 2 may be greater than, for example, 1 mm. In some embodiments, the spacing 1702 can be, for example, 1.2 mm, while in other embodiments the spacing 1702 can be between 0.8 and 1.1 mm, and in yet other embodiments the spacing can be between 0.9 and 1.05 mm. As appreciated by one of ordinary skill in the art having the benefit of this disclosure, the spacing 1702 can be set to any suitable value.

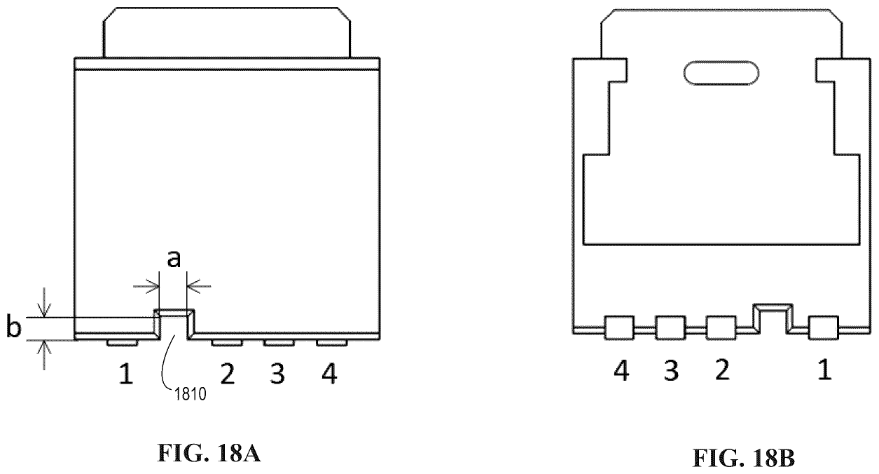

FIGS. 18A-18B show outside views of a surface-mount semiconductor package with a slot, the surface-mount semiconductor package including a controller and a power switch, according to some embodiments. In some embodiments, the package may include one or more power switches. FIGS. 18A-18B illustrate a front view and a bottom view of the surface-mount package, respectively. In the illustrated embodiment, a slot (or recess) 1810 having a width of a and depth of b can be included between the high-voltage pin 1 and the low-voltage pin 2. In this way, a creepage distance between high voltage and low voltage pins can be increased.

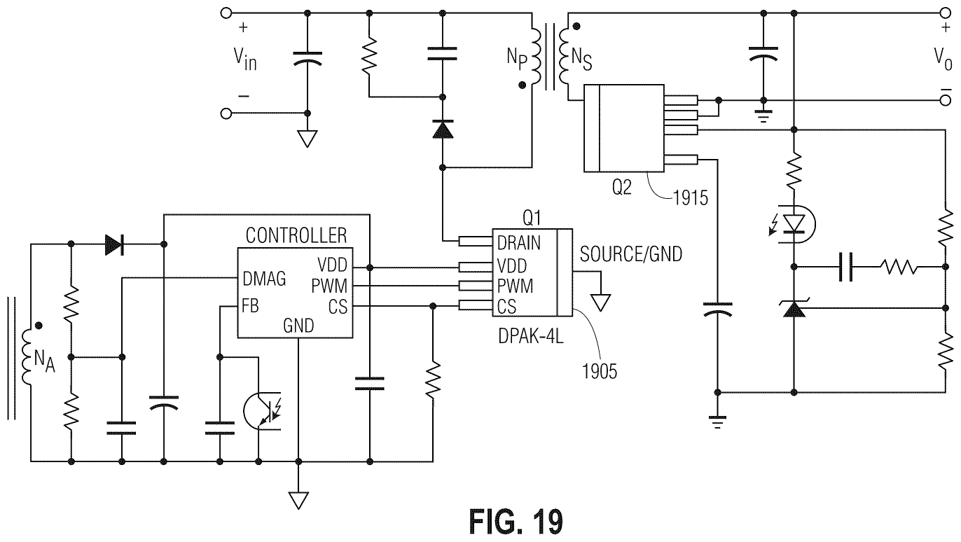

FIG. 19 shows a schematic of a QR flyback converter using a semiconductor package to house a GaN power switch, according to some embodiments. In the illustrated embodiment, the semiconductor package 1905 can include a GaN switch, where the semiconductor package 1905 can have a low voltage pins current sense (CS), input pin that can be arranged to a pulse width modulated (PWM) signal, a low voltage power supply, a high voltage drain pin and a back of the package used for coupling the source terminal to ground. Further, an integrated GaN device 1915 connected on the secondary side may include a GaN switch along with a SR controller. The GaN switch may be used as synchronous rectifier switch on the secondary side.

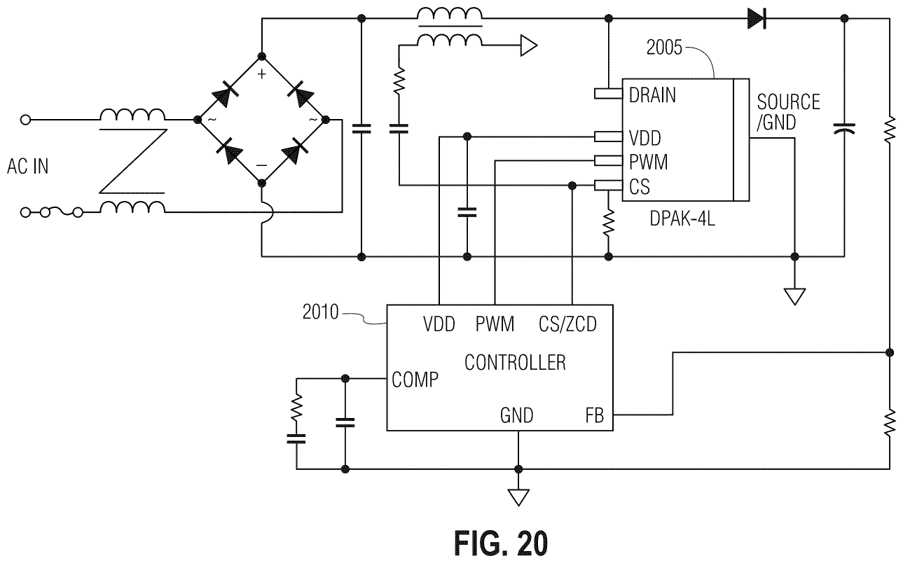

FIG. 20 shows a schematic of a PFC converter using a semiconductor package to house a GaN power switch, according to some embodiments. In the illustrated embodiment, the semiconductor package 2005 can include a GaN switch used for as PFC switch, where the semiconductor package 2005 can have low voltage pins current sense (CS), input pin that can be arranged to a pulse width modulated (PWM) signal, a low voltage power supply, a high voltage drain pin and a back of the package used for coupling the source terminal to ground. A controller 2010 that is similar to controller 102 may be coupled to the semiconductor package 2005, where the controller 2010 may be arranged to control the on/off state of the GaN switch.

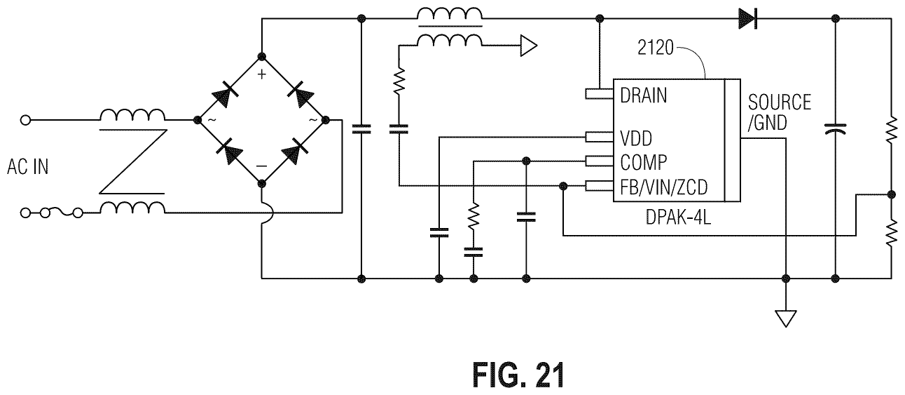

FIG. 21 shows a schematic of a PFC converter using a semiconductor package to house a GaN power switch with a PFC controller, according to some embodiments. In the illustrated embodiment, the semiconductor package 2120 can include a GaN switch used for as PFC switch along with a PFC controller, where the semiconductor package 2120 can have low voltage pins VDD, COMP and FB/VIN/ZCD (as described in the PFC controller section), a high voltage drain pin and a back of the package used for coupling the source terminal to ground.

QR Flyback Controller Co-packaged with Power Switch

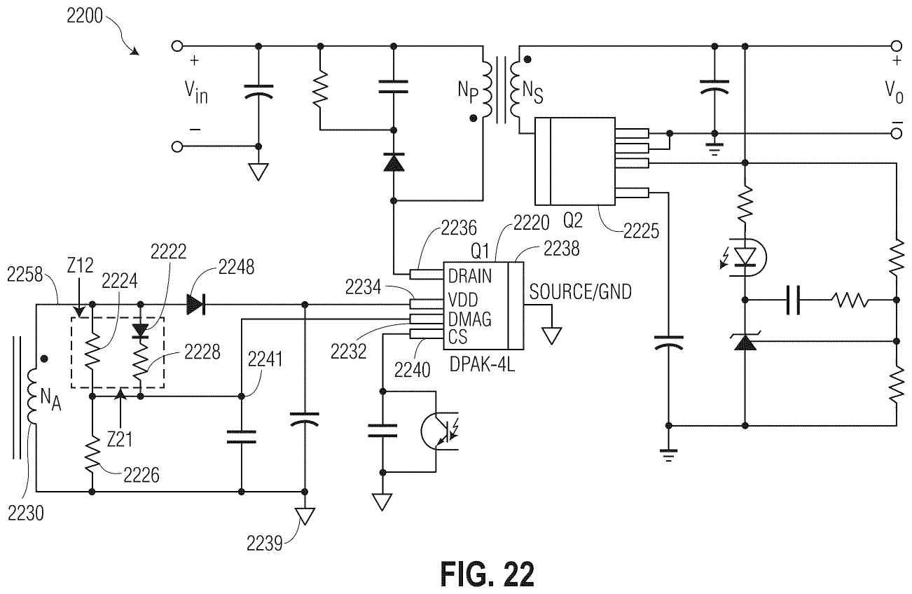

FIG. 22 shows a schematic of a QR flyback converter using an integrated GaN power device in a semiconductor package to co-package a first semiconductor device and a second semiconductor device, according to some embodiments. A semiconductor package 2220 can include the first semiconductor device having a first GaN-based switch along with a second GaN-based switch, and a second semiconductor device having a silicon-based controller IC, according to some embodiments. In the QR flyback converter circuit 2200, a semiconductor package 2220 can include a GaN-based die and the controller circuit. In some embodiments, the controller circuit may include over temperature protection circuits, over current protection circuit, over/under voltage protection circuit and main GaN switch current sensing circuits. The semiconductor package 2220 can have a low voltage pin 2234 used for power supply labeled “VDD”, a low voltage pin 2232 labeled “DMAG” and used as a multi-function pin, and a low voltage pin 2240 used as feedback labeled “FB”, a high voltage drain pin 2236 and a back of the package 2238 used for coupling the source terminal to ground. In some embodiments, the semiconductor package 2220 can include an exposed/extended thermal pad used for the source terminal and/or ground. The VDD pin 2234 can be used for power supply of controller IC, the FB pin 2240 can be used for CV loop feedback through a shunt regulator, and the DMAG pin 2232 can be used for valley switching detection, and also for indirect Vin (input voltage) and Vo (output voltage) detection and protection, and also used for determining a value of a built-in current sense resistor (R_{CS}). In this way, semiconductor package 2220 can reduce number of pins used for operation as compared to using a separate controller circuit and a separate power switch, thus enable system savings, increased reliability and increased power density in a power converter. The

[symbol]

Circuits and techniques disclosed herein enable determination of a value of the built-in current sense resistor inside the semiconductor package 2220, where this value can be used to determine a magnitude and/or a direction of current flowing through the first GaN-based switch. The magnitude and/or direction of flow of current can be used to determine an appropriate gate drive for the gate terminal of the first GaN-based switch. The controller IC may have a current sense (CS) terminal that can be coupled to the second GaN-based switch. The sensed a magnitude and/or a direction of flow of current through the first GaN-based switch can be used for adjusting a drive signal into the gate of the first GaN-based switch and for peak current controlling. The controller circuit may also include a DRV terminal coupled to the gate of the first and second GaN-based switches. A gate drive voltage at the DRV terminal can be adjusted based on the sensed current of the first GaN-based switch and used for optimization of gate drive voltage with built-in EMI control circuitry (EMI optimizer).

By co-packaging the GaN power switch along with the controller IC, the semiconductor package 2220 can reduce the number pins and reduce the external components used in the system. By reducing external components, systems costs may be reduced, system size can be reduced, power density can be increased, and reliability can be improved. In some embodiments, the semiconductor package may be a DPAK 4L having an improved thermal performance compared to a QFN. In various embodies, the DPAK semiconductor package may reduce operating temperature by 5-10° C.

The QR flyback converter circuit 2200 can include a resistor 2224 and a resistor 2226 that are coupled between the auxiliary winding 2230 to ground 2239. The QR flyback converter circuit 2200 can further include a diode 2222 coupled to a first terminal of a resistor 2228, where an anode of the diode 2222 may be coupled to the auxiliary winding 2230. A second terminal of the resistor 2228 may be couped to the node 2241. Node 2241 may be coupled to the multi-function DMAG pin 2232. The anode of the diode 2222 may be coupled to the VDD pin 2234 through a diode 2248. Resistors 2224, 2228 and diode 2222 can add a secondary path from DMAG pin 2232 to the auxiliary winding 2230.

The QR flyback converter circuit 2200 can be arranged to detect Vin voltage using the DMAG pin. For Vin voltage detection, a voltage at the DMAG pin may be clamped to zero by the controller IC. When PWM is ON, a current can be forced out of DMAG pin 2232 into resistor 2228 and resistor 2224 to detect Vin, where a magnitude of Vin can be given by I_{DMAG}*Z21. Z21 is an impedance of resistors 2228, 2224 and diode 2222 looking from node 2241 towards node 2258. The QR flyback converter circuit 2200 can be further arranged to detect Vout by determining a voltage at the DMAG pin (VDMAG). VDMAG can be given by Vaux*Z12/(Z12+R2)=Vo*Na/Ns*Na/Np when PWM=OFF and current discharging period. Vaux is a voltage at node 2258, Z12 is impedance of diode 2222, resistor 2224 and resistor 2228 looking from node 2258 towards node 2241. Na is a number of turns of the auxiliary winding and Ns is a number turns of the secondary winding. The QR flyback converter circuit 2200 can use the detected Vin and Vout for over voltage protection or under voltage protection of the power converter and shut down the main GaN switch when an over/under voltage condition occurs. In some embodiments, the controller can force a current to flow out of DMAG pin (IDMAG) and can measure an effective impedance Rdmag_EFF at the DMAG pin. Once Rdmag_EFF has been determined, the internal current sense resistor Rcs value can be determined based on a look up table.

In some embodiments, a resistor value for a built-in current sensing resistor Rcs can be determined by use of diode 2222 and resistor 2228 and the DMAG pin. To determine a value for the built-in Rcs, a value of Z21 can be determined by Z21=(2224//2226). This can be achieved by forcing a current from the DMAG pin 2232. Based on a detected effective resistance at the DMAG pin, a look-up table can be used to determine a value of Rcs based on the value of Z21. In some embodiments, a method to determine Vin can include: node 2258=−|Vaux1|, VDMAG=0V, a forced current out of DMAG pin may flow through resistor 2224. A magnitude of this current can be given by |Vaux 1|/resistor 2224. This current can correspond to Vin voltage. In various embodiments, a method to determine Vout can include: Voltage at node 2258=+|Vaux2|, VDMAG is a resistor divider between Z12 and resistor 2226, which represents the output voltage.

In some embodiments, a user may select values for the resistors 2224 and 2226 in order to set a threshold setpoint for the over current protection (OCP). During startup, the current source 2414 may increase the current delivered to the DMAG pin until a voltage at the comparator 2416 reaches the Vref voltage. The comparator 2416 may then transmit a signal to the Rcs determination circuit 2428. The Rcs determination circuit may receive signals from the current source 2414 (i.e., the Rcs determination circuit may receive signals that the comparator 2416 has tripped) and receive the voltage at the DMAG pin, and can correspondingly determine a value of an equivalent parallel resistors (Z21 and/or Z12). The Rcs determination circuit may employ the determined value of the equivalent parallel resistors using a lookup table to determine a value of the current sense Rcs resistor 2424. The determined Rcs resistor value can be used in for overcurrent protection (OCP) circuit to set a threshold value for OCP, for example, 8 A. The logic circuit can then adjust the value of the Rcs resistor 2424 to an appropriate resistance value such that when a current through the GaN-based switch 2402 reaches the threshold, for example 8A, the current sense comparator trips and shuts down the DRV signal.

In this way, the determined values of the effective resistance at the DMAG pin can be used by the controller 2498 to trim the OCP threshold.

In some embodiments, a method for determining a built-in value for the current sense resistor Rcs may include: 1) For each power cycle, one time detection of the effective impedance Rdmag_EFF at the DMAG pin. The Rdmag_EFF can be used to determine a value of the current sense resistor Rcs. A current can be forced out of the DMAG pin and measure a voltage at node 2241. Next, a cycle-by-cycle operation may include steps 2A and 2B: 2A) Voltage at node 2241 is forced to zero when PWM is ON and a current is forced out of the DMAG pin and measured in order to determine a value of a voltage at node V2258 (Vaux). 2B) A current is forced out of the DMAG pin when PWM is OFF. The current value may be increased in known values, for example, 100 uA, 150 uA, 200 uA, 250 uA, etc. When the voltage at the input is greater than a Vref value, for example, 0.5 V, the effective impedance at the DMAG pin is recorded.

In some embodiments, a semiconductor package 2225 on the secondary side can be used where the semiconductor package 2225 can include a GaN switch, used as a synchronous rectifier switch, co-packaged with a synchronous rectifier controller circuit.

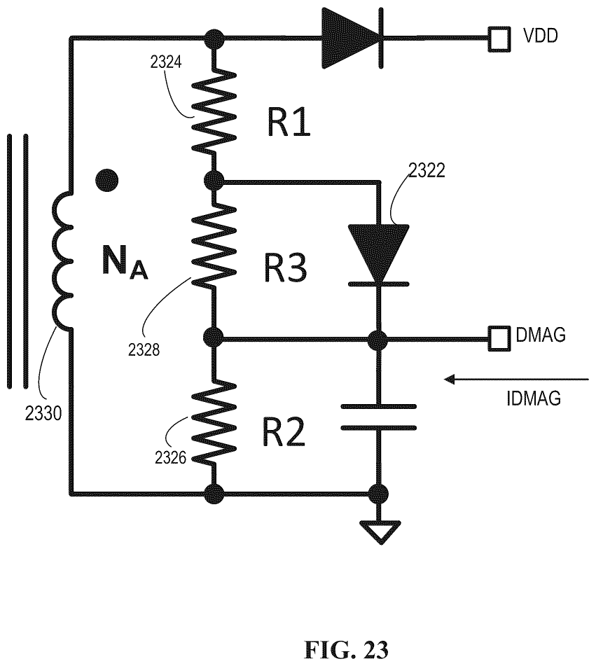

FIG. 23 shows an alternate schematic for determining Rdmag_EFF value, according to some embodiments. In FIG. 23, a QR flyback converter may include an auxiliary winding 2330, a resistor 2324 (R1), a resistor 2326 (R2), a resistor 2328 (R3) and a diode 2322. In this embodiment, a method of determining Rdmag_EFF value values includes: 1) when IC power on and before the power converter starts switching, force current out of DMAG pin. Based on the effective impedance at the DMAG pin, a value of built-in Rcs can be determined. Hold the value of Rcs for the duration of power up; 2) When primary side is off and in reverse time, VDMAG can sense secondary voltage information to determine for OVP.

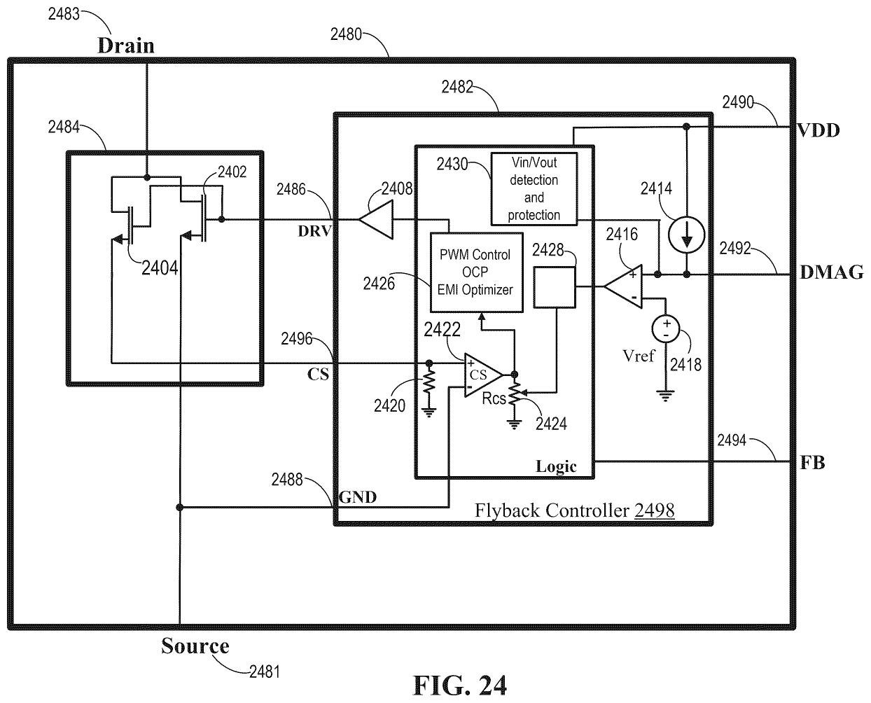

FIG. 24 illustrates a diagram of an integrated GaN power device that includes a flyback controller IC and a GaN switch, according to some embodiments. In the illustrated embodiment, a semiconductor package 2480 can be used for integrating a first semiconductor device 2484 and a second semiconductor device 2482. In some embodiments, the first semiconductor device 2484 can be a GaN-based die. In various embodiments, the second semiconductor device 2482 may be a silicon-based die having a flyback controller IC 2498. In some embodiments, the flyback controller IC can be a QR flyback controller IC. The first semiconductor device 2484 can include a first GaN-based switch 2402 having a first source, a first gate and a first drain, and a second GaN-based switch 2404 having a second source, a second gate and a second drain. In some embodiments, the first gate may be coupled to the second gate and the first drain may be coupled to the second drain. In various embodiments, the first GaN-based switch may be a first transistor, and the second GaN-based switch may be a second transistor.

The semiconductor package 2480 can include an external source terminal 2481, an external drain terminal 2483, an external feedback (FB) terminal 2494, an external multi-function (DMAG) terminal 2492, and an external power supply (VDD) terminal 2490. The first source can be coupled to the external source terminal 2481. The first and second drains can be coupled to the external drain terminal 2483. The flyback controller IC 2498 may have a gate drive terminal 2486 (DRV) that can be coupled to the first and second gates. In some embodiments, an electromagnetic interference (EMI) control management circuit may be coupled to the DRV terminal. A ground node 2488 of the flyback controller IC 2498 may be coupled to the external source terminal 2481. The external power supply VDD terminal 2490 can be coupled to a power supply terminal of the flyback controller IC 2498. The DMAG terminal 2492 can be coupled to a multi-functional terminal of the flyback controller IC 2498. The flyback controller IC 2498 may have a current sense (CS) terminal 2496 coupled to the second source.

The CS terminal 2496 may be arranged to receive a signal from the second GaN-based switch 2404 that is indicative of a magnitude and/or a direction of a current flowing through the first GaN-based switch 2402. In some embodiments, the flyback controller IC 2498 may include an amplifier 2422 coupled to the CS terminal 2496 and a resistor 2420 coupled to the CS terminal 2496. In some embodiments, the amplifier 2422 may be a comparator. The amplifier 2422 may generate a current at its output. An output of the amplifier 2422 may be coupled to a current sense resistor 2424 (Rcs).

A value of the current sense resistor 2424 (Rcs) can be determined by the Rcs determination circuit 2428 based on an effective impedance at the DMAG pin. The determined value of the current sense resistor 2424 (Rcs) can be used to determine a value of magnitude of the current flowing through the switch 2402. A PWM control circuit 2426 can transmit PWM signals to the driver circuit 2408 based on the magnitude of the current flowing through the switch 2402. In some embodiments, a direction of the current flowing the switch 2402 can be determined. The PWM control circuit 2426 can transmit PWM signals based on at least a magnitude or the direction of the current flowing through the switch 2402. The flyback controller 2498 may further include a Vin/Vout detection circuit 2430. The flyback controller 2498 may also include a driver circuit 2408 coupled to first and second gates. The flyback controller 2498 may include a current source 2414 coupled to the DMAG terminal 2492. In some embodiments, the PWM control circuit 2426 may include over current protection circuits, EMI optimizer circuits and over/under voltage protection circuits.

The flyback controller 2498 may further include a comparator 2416 having its first terminal coupled to the DMAG terminal 2492 and its second terminal coupled to a reference voltage Vref 2418. In some embodiments, a value of the reference voltage may be, for example, 0.5 V. A current flowing through the current source 2414 can be forced out of the DMAG pin and a voltage at the DMAG pin can be compared to the Vref. In some embodiments, the current source 2414 may include multiple individual current sources having values, for example, 100 uA, 50 uA, 200 uA, 250 uA. Each current source may be forced out through the DMAG pin until a voltage at the DMAG pin is greater than the Vref. Upon tripping of the comparator 2416, a corresponding signal may be transmitted to the Rcs determination circuit 2428. Based on the transmitted signal, a value for the current sense resistor 2424 can be selected using a lookup table.

The first semiconductor device 2484 may be coupled to the second semiconductor device 2482 through wire bonds and/or clips. In some embodiments, the circuits on the second semiconductor device may be arranged to detect gate drive signal, current sense information, temperature, and various other operating parameters, and generate protection signals for the high-voltage power switch such as over current protection, over/under voltage protection signals and over temperature protection signals. The second semiconductor device may be electrically coupled to the low-voltage signal pins through wire bonds and/or clips.

In some embodiments, combination of the circuits, packages and methods disclosed herein can be utilized to provide a power factor correction controller IC, a QR flyback controller IC as well as integrated GaN power devices. Although circuits and methods are described and illustrated herein with respect to several particular configuration of PFC converter circuit and QR flyback converter circuit and particular semiconductor packages, embodiments of the disclosure are suitable for other power converter topologies such as, but not limited to, power converters such as, but not limited to, AHB converters utilizing silicon power switches, GaN power switches, or silicon carbide power switches. Further, embodiments of the disclosure are suitable for use in other semiconductor packages, such as, but not limited to, flat no-leads package, and the like.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as “bottom or “top” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

In some embodiments, an electronic system may include the following:
1. An electronic component comprising:
a base;
a first semiconductor device attached to the base and including:
a first Gallium nitride (GaN)-based switch having a first gate, a first source and a first drain, wherein the first gate is arranged to control a current flow between the first source and the first drain;
a second GaN-based switch having a second source, a second gate and a second drain, wherein the second gate is coupled to the first gate and the second drain is coupled to the first drain;
   a second semiconductor device attached to the base and including:
a driver circuit coupled to the first and second gates, the driver circuit arranged to control on and off states of the first and second GaN-based switches;
a logic circuit arranged to:
detect a magnitude of the current flow via a first signal received from the second source; and
control the driver circuit to turn off the first and second GaN-based switches when the detected magnitude of the current flow exceeds a threshold current value; and
an electrically insulative encapsulant at least partially encapsulating the base, the first semiconductor device and the second semiconductor device.
2. The electronic component of claim 1, wherein the logic circuit is coupled to an external circuit and wherein the threshold current value is at least partially determined by the external circuit.
3. The electronic component of claim 2, wherein the external circuit comprises a resistor, and wherein the threshold current value is at least partially based on a resistance of the resistor.
4. The electronic component of claim 1, wherein the logic circuit includes an adjustable resistor and the threshold current value is at least partially based on a resistance of the adjustable resistor.
5. The electronic component of claim 1, further comprising a sense resistor coupled to the second source and wherein a voltage at the sense resistor corresponds to the first signal.
6. The electronic component of claim 5, wherein the sense resistor is disposed on the second semiconductor device.
7. The electronic component of claim 1, wherein the driver circuit synchronously controls on and off states of the first and the second GaN-based switches.
8. An electronic component comprising:
a first semiconductor device including:
a first Gallium nitride (GaN)-based switch having a first gate, a first source and a first drain, wherein the first gate is arranged to control a current flow between the first source and the first drain;
a second GaN-based switch having a second source, a second gate and a second drain, wherein the second gate is coupled to the first gate and the second drain is coupled to the first drain;
a second semiconductor device including:
a driver circuit coupled to the first and second gates, the driver circuit arranged to control on and off states of the first and second GaN-based switches;
a logic circuit arranged to:
detect a magnitude of the current flow via a first signal received from the second source; and
control the driver circuit to turn off the first and second GaN-based switches when the detected magnitude of the current flow exceeds a threshold current value; and
an electrically insulative encapsulant at least partially encapsulating the first semiconductor device and the second semiconductor device;
a first external terminal disposed at an exterior surface of the electronic component and coupled to the first drain; and
a second external terminal disposed at the exterior surface of the electronic component and coupled to the first source.
9. The electronic component of claim 8, wherein the logic circuit is coupled to an external circuit via a third external terminal and wherein the threshold current value is at least partially determined by the external circuit.
10. The electronic component of claim 9, wherein the external circuit comprises a resistor, and wherein the threshold current value is at least partially based on a resistance of the resistor.
11. The electronic component of claim 9, wherein the first external terminal is coupled to a primary winding of a transformer, and wherein the third external terminal is coupled to a secondary winding of the transformer.
12. The electronic component of claim 11, wherein the logic circuit detects an input voltage at the primary winding of the transformer via the third external terminal.
13. The electronic component of claim 11, wherein the secondary winding is a first secondary winding and wherein the logic circuit detects an output voltage at a second secondary winding of the transformer via the third external terminal.
14. The electronic component of claim 8, wherein the logic circuit includes an adjustable resistor and wherein the logic circuit controls the driver circuit to turn off the first and second GaN-based switches at least partially based on a resistance of the adjustable resistor.
15. The electronic component of claim 8, further comprising a sense resistor coupled to the second source and wherein the logic circuit detects the magnitude of the current flow via a voltage at the sense resistor.
16. The electronic component of claim 15, wherein the sense resistor is disposed on the second semiconductor device.
17. A method of operating an electronic component, the method comprising:
sensing an external circuit at a first external terminal, wherein the first external terminal is at an exterior surface of the electronic component;
adjusting a value of a variable resistor in response to the sensing the external circuit, wherein the variable resistor is disposed within the electronic component;
conducting a current between a second external terminal and a third external terminal via a first gallium nitride (GaN)-based transistor, wherein the first GaN-based transistor is disposed within the electronic component and wherein the second and third external terminals are at the exterior surface of the electronic component;
sensing the conducted current via a second GaN-based transistor disposed within the electronic component; and
transitioning the first GaN-based transistor to an off state based at least on the value of the variable resistor and the sensed conducted current.
18. The method of claim 17, wherein the external circuit includes a resistor and wherein the sensing includes sensing a resistance value of the resistor.
19. The method of claim 17, wherein first GaN-based switch includes a first gate, a first source and a first drain and wherein the second GaN-based switch includes a second source, a second gate and a second drain, and wherein the second gate is coupled to the first gate and the second drain is coupled to the first drain.
20. The method of claim 17, further comprising sensing a voltage of a transformer winding via the first external terminal.
21. A power converter circuit comprising:
a power factor controller including:
   an input terminal arranged to detect a first voltage representative of an output voltage of the power converter circuit and to detect a second voltage proportional to an input voltage of the power converter circuit;
   a drive terminal for transmitting a drive signal to a gate of a switch;
   a logic circuit arranged to add the first and second voltages during an on-time of the power converter circuit to generate a first signal;
   a delay circuit arranged to generate a zero current detection (ZCD) signal based on the first and second voltages at the input terminal; and
   a controller circuit arranged to generate the drive signal in response to the first signal and the ZCD signal.
22. The power converter circuit of claim 21, wherein the second voltage is detected by determining a voltage drop across a first transformer winding, wherein the first transformer winding is magnetically coupled to a second transformer winding and the second transformer winding is coupled to an input node of the power converter circuit.
23. The power converter circuit of claim 22, wherein the power factor controller further comprises a brown-out protection circuit arranged to generate a brown-out signal using the first signal.
24. The power converter circuit of claim 23, wherein the power factor controller further comprises an over-voltage protection circuit arranged to generate an over-voltage signal using an average of the first voltage.
25. A method operating a power converter circuit, the method comprising:
providing a power factor controller having an input terminal, a drive terminal, a logic circuit, a delay circuit and a controller circuit, wherein the drive terminal is arranged to transmit a drive signal to a gate of a switch;
detecting, at the input terminal, a first voltage representative of an output voltage of the power converter circuit;
detecting, at the input terminal, a second voltage proportional to an input voltage of the power converter circuit;
adding, by the logic circuit, the first and second voltages during an on-time of the power converter circuit to generate a first signal;
generating, by the delay circuit, a zero current detection (ZCD) signal based on the first and second voltages at the input terminal; and
generating, by the controller circuit, the drive signal in response to the first signal and the ZCD signal.

What is claimed is:

1. An electronic component comprising:
a base;
a first semiconductor device attached to the base and including:
a first Gallium nitride (GaN)-based switch having a first gate, a first source and a first drain, wherein the first gate is arranged to control a current flow between the first source and the first drain;
a second GaN-based switch having a second source, a second gate and a second drain, wherein the second gate is coupled to the first gate and the second drain is coupled to the first drain;
a second semiconductor device attached to the base and including:
a logic circuit coupled to the second source and arranged to detect a magnitude of the current flow; and
a driver circuit coupled to the first and second gates, the driver circuit arranged to control on and off states of the first and second GaN-based switches; and
an electrically insulative encapsulant at least partially encapsulating the base, the first semiconductor device and the second semiconductor device.

2. The electronic component of claim 1, further comprising a first external terminal coupled to the first drain, a second external terminal coupled to the first source, and a third external terminal coupled to the logic circuit, the third external terminal arranged to transmit a signal corresponding to the detected magnitude of the current flow.

3. The electronic component of claim 1, further comprising a resistor coupled to the second source and wherein the logic circuit detects a voltage drop across the resistor that is proportional to the magnitude of the current flow.

4. The electronic component of claim 3, wherein the resistor is disposed within the second semiconductor device.

5. The electronic component of claim 1, wherein the driver circuit synchronously controls on and off states of the first and the second GaN-based switches.

6. The electronic component of claim 2, wherein the electronic component further comprises a fourth external terminal coupled to the logic circuit, wherein the fourth external terminal is arranged to receive pulse width modulated signals.

7. The electronic component of claim 6, further comprising a fifth external terminal, the fifth external terminal arranged to receive a power supply.

8. An electronic component comprising:
a first semiconductor device including:
a first Gallium nitride (GaN)-based switch having a first gate, a first source and a first drain, wherein the first gate is arranged to control a current flow between the first source and the first drain;
a second GaN-based switch having a second source, a second gate and a second drain, wherein the second gate is coupled to the first gate and the second drain is coupled to the first drain;
a second semiconductor device including:
a driver circuit coupled to the first and second gates, the driver circuit arranged to control on and off states of the first and second GaN-based switches;
a logic circuit arranged to:
detect a magnitude of the current flow via a first signal received from the second source; and
control the driver circuit to turn off the first and second GaN-based switches when the detected magnitude of the current flow exceeds a threshold current value; and
an electrically insulative encapsulant at least partially encapsulating the first semiconductor device and the second semiconductor device;
a first external terminal disposed at an exterior surface of the electronic component and coupled to the first drain; and
a second external terminal disposed at the exterior surface of the electronic component and coupled to the first source.

9. The electronic component of claim 8, wherein the electronic component further comprises a third external terminal coupled to the logic circuit, the third external terminal arranged to transmit a signal corresponding to the detected magnitude of the current flow.

10. The electronic component of claim 8, further comprising a resistor coupled to the second source and wherein the logic circuit detects a voltage drop across the resistor that is proportional to the magnitude of the current flow.

11. The electronic component of claim 10, wherein the resistor is disposed within the second semiconductor device.

12. The electronic component of claim 8, wherein the driver circuit synchronously controls on and off states of the first and the second GaN-based switches.

13. The electronic component of claim 9, further comprising a fourth external terminal coupled to the logic circuit, wherein the fourth external terminal is arranged to receive pulse width modulated signals.

14. The electronic component of claim 13, further comprising a fifth external terminal, the fifth external terminal arranged to receive a power supply.

15. A method of operating an electronic component, the method comprising:
receiving an input signal at a first external terminal;
transmitting the input signal to a driver circuit disposed on a first semiconductor device disposed within the electronic component, wherein the driver circuit transmits first and second drive signals in response to receiving the input signal;
transitioning a first Gallium nitride (GaN)-based switch between a first on state and a first off state in response to receiving the first drive signal, wherein the first GaN-based switch is disposed on a second semiconductor device disposed within the electronic component and wherein the first GaN-based switch controls a flow of a current between a second external terminal of the electronic component and a third external terminal of the electronic component;
transitioning a second Gallium nitride (GaN)-based switch between a second on state and a second off state in response to receiving the second drive signal, wherein the second GaN-based switch is disposed on the second semiconductor device;
detecting a magnitude of the current via a detection circuit disposed on the second semiconductor device, wherein the detection circuit is coupled to the second GaN-based switch; and
generating an output signal at a fourth external terminal, wherein the output signal corresponds to the magnitude of the current.

16. The method of claim 15, wherein the detection circuit comprises a resistor disposed within the first semiconductor device, the resistor being coupled to the fourth external terminal.

17. The method of claim 15, the transitioning of the first and second GaN-based switches occurs synchronously.

18. The method of claim 15, further comprising providing power to the first semiconductor device via a fifth external terminal.

19. The method of claim 15, further comprising detecting a direction of the current via the detection circuit.

20. The method of claim 19, wherein the generated output signal corresponds to the magnitude and the direction of the current.
